(19) United States
(12) Patent Application Publication
(10) Pub. No.: US 2026/0304998 A1
(43) Pub. Date: Oct. 1, 2026

(54) PRODUCTION LINE FOR PRODUCING SOLAR CELL

(71) Applicant: LAPLACE RENEWABLE ENERGY TECHNOLOGY CO., LTD., Shenzhen (CN)

(72) Inventors: Jiaji LIN, Shenzhen (CN); Aisuo PANG, Shenzhen (CN); Tairong ZHU, Shenzhen (CN)

(73) Assignee: LAPLACE RENEWABLE ENERGY TECHNOLOGY CO., LTD., Shenzhen (CN)

(21) Appl. No.: 19/697,839

(22) Filed: Jun. 4, 2026

Related U.S. Application Data
(63) Continuation-in-part of application No. 18/438,079, filed on Feb. 9, 2024.
Application No. 18/438,079 is a continuation of application No. PCT/CN2022/131271, filed on Nov. 11, 2022.

(30) Foreign Application Priority Data
Nov. 26, 2021 (CN) 202111419221.9

(51) Int. Cl. H10F 71/00; H10F 77/70

(52) U.S. Cl. CPC H10F 71/1224; H10F 71/128; H10F 71/129; H10F 77/703

(57) ABSTRACT

A production line for producing a solar cell includes a texturing device, a boron diffusion device, an etching device, a PECVD device, a passivation system and an electrode manufacturing system. The texturing device is configured to perform a texturing process of an N-type silicon wafer. The boron diffusion device is configured to perform a boron diffusion process. The etching device is configured to perform an etching process and a polishing process. The PECVD device is configured to form a tunneling oxide layer and a silicon layer on a back side of the silicon wafer. The annealing device is configured to perform an annealing process. The passivation system is configured to perform a passivation layer process, a front film process and a back film process. The electrode manufacturing system is configured to perform a preparation process of electrodes on two sides of the silicon wafer to form a solar cell.

### CROSS-REFERENCE TO RELATED APPLICATIONS

This application is a continuation-in-part of U.S. Application No. 18/438,079, filed on Feb.9, 2024, which is a continuation of International Application No. PCT/CN2022/131271, filed on Nov. 11, 2022, which claims priority to Chinese Patent Application No. 202111419221.9, filed on Nov.26, 2021. All of the aforementioned applications are hereby incorporated by reference in their entireties.

### TECHNICAL FIELD

The present application relates to the field of solar cell manufacturing technologies, and in particular, to a production line for producing a solar cell.

### BACKGROUND

A mainstream technology for P-type monocrystalline solar cells is a passivated emitter and rear cell (PERC) technology. The PERC technology has a simple manufacturing process and low cost. An addition of a selective emitter (SE) technology enhances conversion efficiency of cells. As efficiency of P-type cells approaches a theoretical limit, an N-type cell technology is expected to become a mainstream direction for future development. Compared to the P-type cells, N-type cells offer advantages such as higher conversion efficiency, higher bifaciality, lower temperature coefficient, no light-induced degradation, good weak light effect, and longer carrier lifetime. Since the technologies used for the N-type cells differ from the technologies used for the P-type cells, a production equipment for the N-type cells is also different from a production equipment for the P-type cells. Therefore, an equipment used for PERC production lines may not be adapted for the N-type cells, resulting in idle PERC production line equipment and waste.

The present application provides a production line for producing a solar cell, applied to manufacture an N-type silicon wafer into a solar cell. The production line for producing the solar cell includes: a texturing device, a boron diffusion device, an etching device, a PECVD device, an annealing device, a passivation system and an electrode manufacturing system. The texturing device is configured to perform a texturing process of an N-type silicon wafer. The boron diffusion device is configured to perform a boron diffusion process of the N-type silicon wafer. The etching device is configured to perform an etching process and a polishing process of the N-type silicon wafer. The PECVD device is configured to form a tunneling oxide layer and a silicon layer on the N-type silicon wafer. The annealing device is configured to perform an annealing process of the N-type silicon wafer. The passivation system is configured to perform a passivation layer process, a front film process and a back film process of the N-type silicon wafer. The electrode manufacturing system is configured to perform a preparation process of electrodes on two sides of the N-type silicon wafer to form a solar cell.

### BRIEF DESCRIPTION OF THE DRAWINGS

FIG. 1 is a schematic diagram of a cell structure according to an embodiment of the present application.

FIG. 2 is a schematic flowchart of a cell preparation process according to an embodiment of the present application.

FIG. 3 is a schematic structural diagram of a production line for producing a solar cell according to an embodiment of the present application.

FIG. 4 is a schematic diagram of a texturing device according to an embodiment of the present application.

FIG. 5 is a schematic diagram of a boron diffusion device according to an embodiment of the present application.

FIG. 6 is a schematic diagram of a loading and unloading system of a boron diffusion device according to an embodiment of the present application.

FIG. 7 is a schematic diagram of a loading and unloading system of another boron diffusion device according to another embodiment of the present application.

FIG. 8 is a schematic diagram of a loading and unloading system of another boron diffusion device according to another embodiment of the present application.

FIG. 9 is a schematic diagram of a carrier in a boron diffusion device according to an embodiment of the present application.

FIG. 10 is an enlarged schematic diagram of region A in FIG. 9.

FIG. 11 is a schematic diagram of a first carrier conveying and purifying system and a first furnace tube system of a boron diffusion device according to an embodiment of the present application.

FIG. 12 is a schematic diagram of an internal structure of a first carrier conveying and purifying system of a boron diffusion device according to an embodiment of the present application.

FIG. 13 is a schematic diagram of a first carrier carrying system of a first carrier conveying and purifying system according to an embodiment of the present application.

FIG. 14 is a schematic diagram of a first carrier pushing system of a first carrier conveying and purifying system according to an embodiment of the present application.

FIG. 15 is a schematic diagram of a first transmission system of a first carrier conveying and purifying system according to an embodiment of the present application.

FIG. 16 is a schematic diagram of an internal structure of a first furnace tube system of a boron diffusion device according to an embodiment of the present application.

FIG. 17 is a schematic diagram of a laser doping device according to an embodiment of the present application.

FIG. 18 is a schematic diagram of an oxidation system according to an embodiment of the present application.

FIG. 19 is a schematic diagram of an etching device according to an embodiment of the present application.

FIG. 20 is a schematic diagram of a phosphorus diffusion device according to an embodiment of the present application.

FIG. 21 is a schematic diagram of a passivation system according to an embodiment of the present application.

FIG. 22 is a schematic diagram of an electrode manufacturing system according to an embodiment of the present application.

FIG. 23 is a schematic diagram of an annealing device according to an embodiment of the present application.

### DETAILED DESCRIPTION OF THE EMBODIMENTS

Implementations of the present application are illustrated below through specific embodiments.

Illustrations provided in the following embodiments only illustrate basic concept of the present application in a schematic manner. The illustrations only show components related to the present application and are not drawn based on number, shape, and size of the components during an actual implementation. Type, quantity, and proportion of each component during the actual implementation may be arbitrarily changed, and component layout type thereof may alternatively be more complex.

All directional indications (such as up, down, left, right, front, back, horizontal, lateral, and longitudinal.) in the embodiments of the present application are only used to explain relative position relationship, motion situation, and the like between multiple components in a specific posture. If the specific posture changes, the directional indication alternatively changes accordingly.

The "connection" mentioned in the present embodiment may be a physical connection, or may be a process connection. For example, a connection between a first device and a second device may be understood as using a robotic arm to transport a product processed by the first device to the second device for further processing.

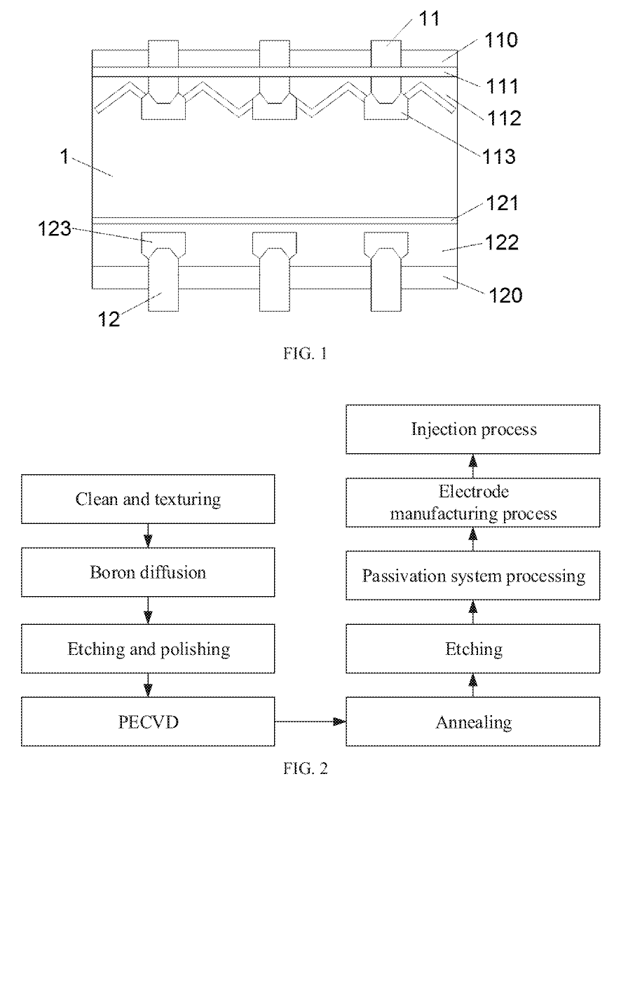

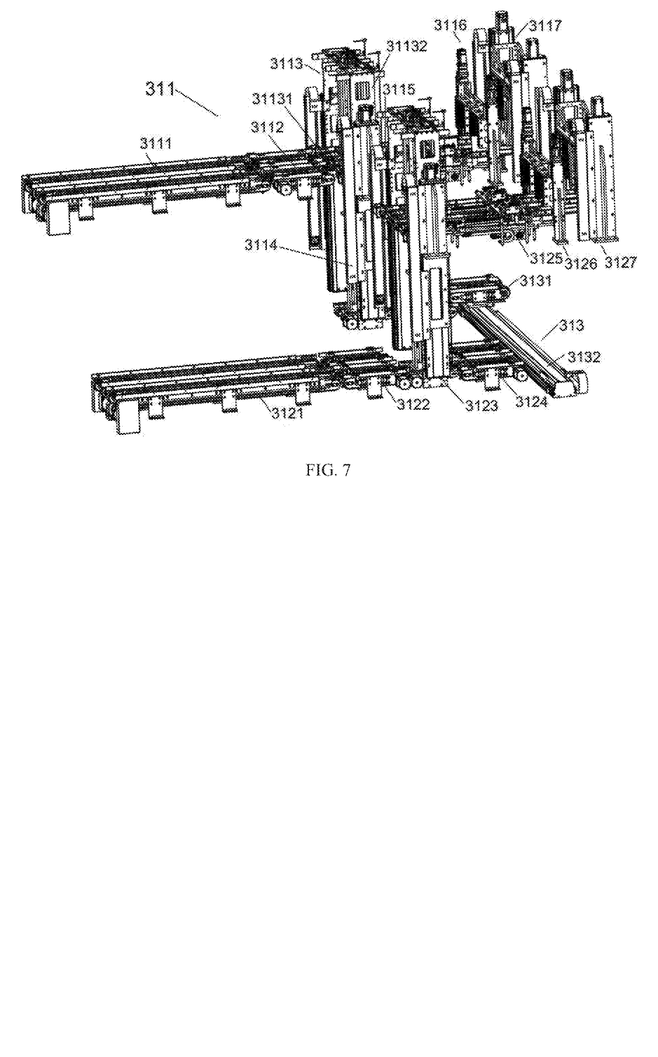

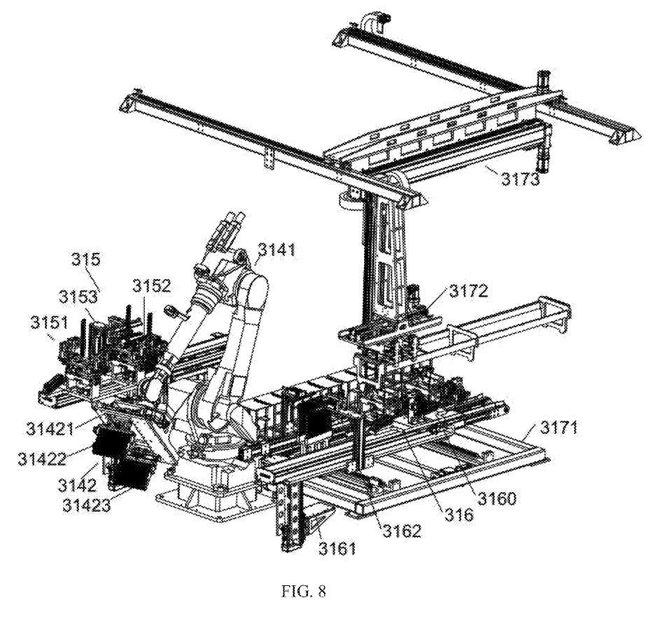

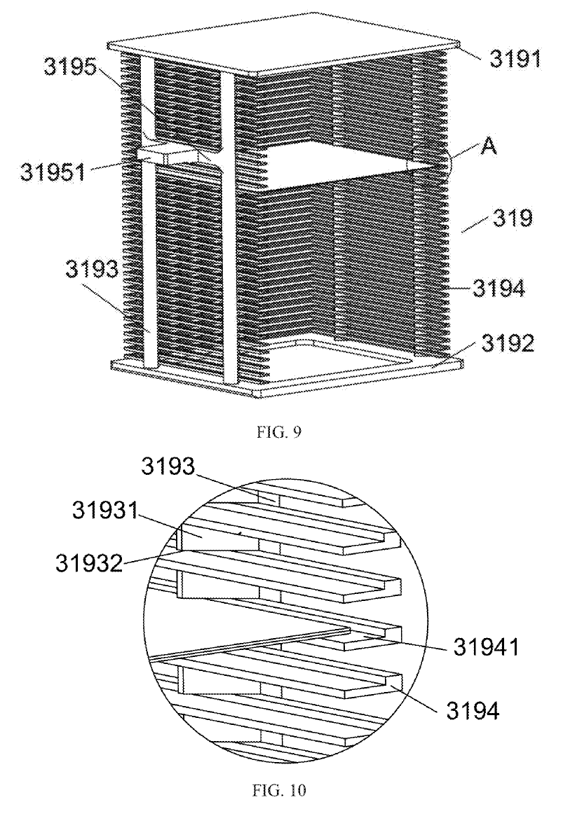

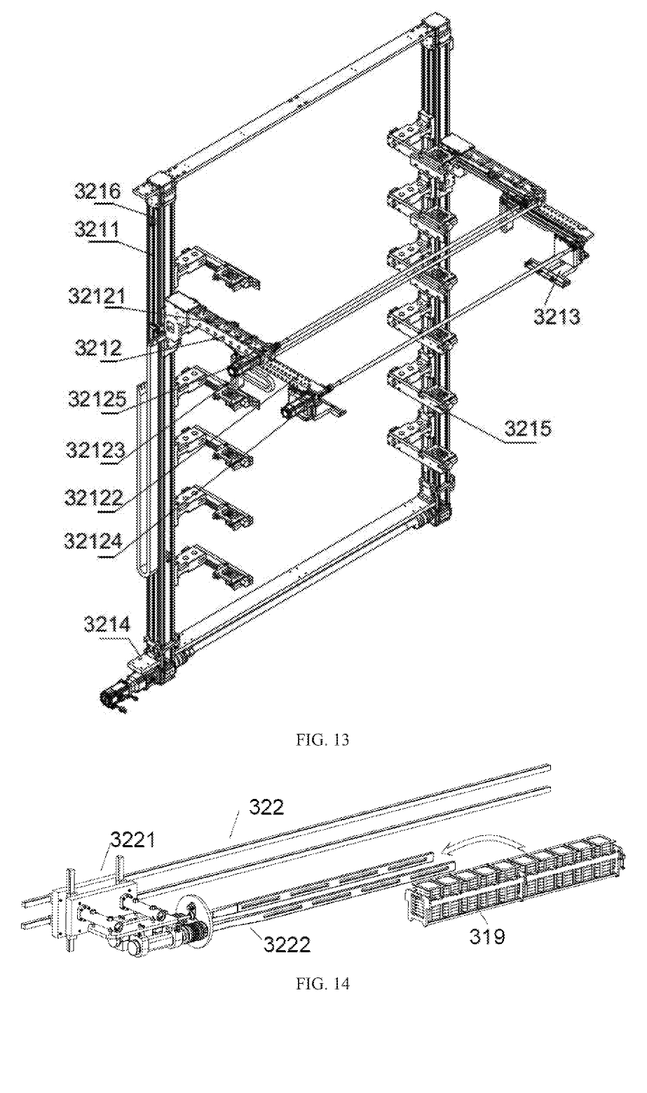

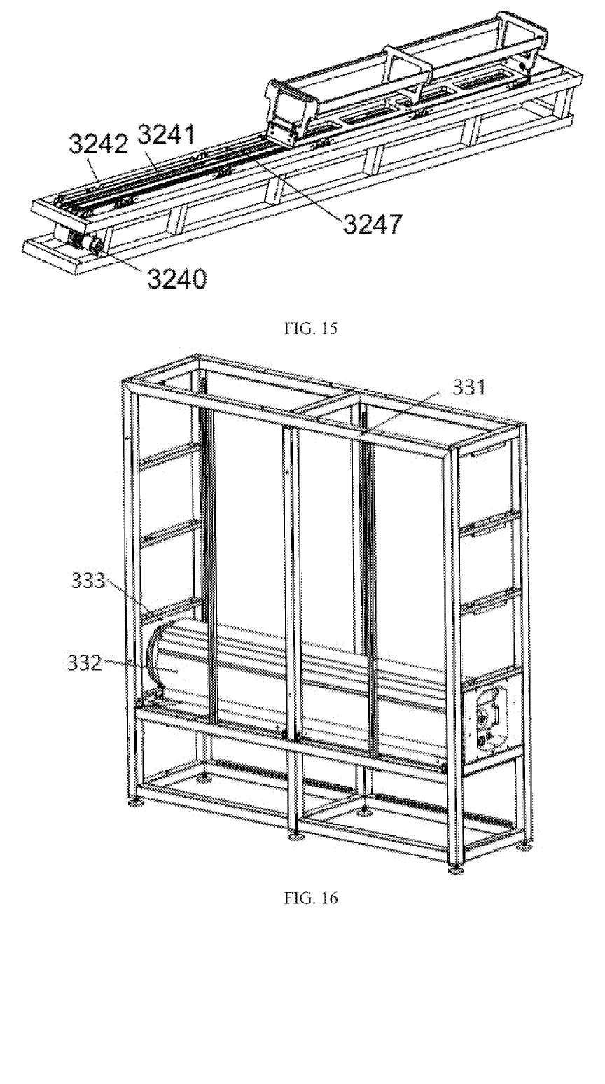

As shown in FIG. 1 to FIG. 23, an embodiment of the present application provides a production line 10 for producing a solar cell. The production line 10 for producing the solar cell is applied to manufacture an N-type silicon wafer 1 into a solar cell. The production line 10 for producing the solar cell includes: a texturing device 2, a heat treatment system 3, an etching device 6, a plasma enhanced chemical vapor deposition (PECVD) device 98, a passivation system 8 and an electrode manufacturing system 9. The heat treatment system 3 includes a boron diffusion device 3A.

In some other embodiments, the heat treatment system 3 may further include a low-pressure chemical vapor deposition (LPCVD) device.

The texturing device 2 is configured to perform a texturing process of the N-type silicon wafer 1. The boron diffusion device 3A is configured to perform a boron diffusion process of the N-type silicon wafer 1 to form a boron-doped region 112. The boron-doped region 112 is formed, for example, on a back side of the N-type silicon wafer. The etching device 6 is configured to perform an etching process and a polishing process of the N-type silicon wafer 1. The polishing process is used for chemical polishing of the N-type silicon wafer. The PECVD device 98 is configured to form a tunneling oxide layer and a silicon layer on the back side of the N-type silicon wafer 1. The annealing device 99 is configured to perform an annealing process of the N-type silicon wafer 1. The passivation system 8 is configured to perform a passivation layer process, a front film process and a back film process of the N-type silicon wafer 1. The electrode manufacturing system 9 is configured to perform a preparation process of electrodes on two sides of the N-type silicon wafer 1 to form the solar cell. Exemplarily, the silicon layer includes a doped amorphous silicon layer, and a doping element includes phosphorus.

In some embodiments, the production line 10 for producing the solar cell further includes an annealing device configured to perform an annealing process of the N-type silicon wafer. In some other embodiments, PECVD device 98 is further configured to perform an annealing process on the N-type silicon wafer.

In one possible implementation of the present embodiment, the production line for producing the solar cell further includes a phosphorus diffusion device 7. The phosphorus diffusion device 7 is configured to perform a phosphorus diffusion process of the N-type silicon wafer. The phosphorus diffusion process is performed after formation of the intrinsic amorphous silicon layer. The phosphorus diffusion process serves to convert the intrinsic amorphous silicon layer into a phosphorus-doped polycrystalline silicon layer.

As shown in FIG. 4, the texturing device 2 includes a texturing loading apparatus 20, a texturing pre-cleaning tank 21, a texturing apparatus 22, a texturing post-cleaning tank 23, a texturing pickling tank 24, a texturing pre-dehydration tank 25, a texturing drying tank 26, and a texturing unloading apparatus 27 connected in sequence. The texturing loading apparatus 20 is configured to move the N-type silicon wafer 1 to the texturing pre-cleaning tank 21 for cleaning. The texturing pre-cleaning tank 21 is configured to remove an impurity on a surface of the N-type silicon wafer 1 to prepare for subsequent texturing. The texturing apparatus 22 is configured to form a texture structure on the surface of a pre-cleaned N-type silicon wafer 1 by using an alkaline solution. For example, the alkaline solution may be sodium hydroxide or potassium hydroxide. In general, the textured structure is formed in a shape of multiple triangles to increase the number of light refractions on the surface of the N-type silicon wafer 1, thereby increasing an optical path length of a light in the N-type silicon wafer 1, and improving utilization of sunlight. The texturing post-cleaning tank 23 is configured to clean the N-type silicon wafer 1 after the texture structure is formed on the surface of the N-type silicon wafer 1 to remove an impurity on the surface of the N-type silicon wafer 1. The texturing pickling tank 24 is configured to pickle the N-type silicon wafer with acid to neutralize the alkaline solution and remove a metal ion from the surface of the N-type silicon wafer 1. The texturing pre-dehydration tank 25 is configured to dehydrate the N-type silicon wafer 1 after the N-type silicon wafer 1 is pickled. The texturing drying tank 26 is configured to dry the N-type silicon wafer 1 after the N-type silicon wafer 1 is dehydrated. The texturing unloading apparatus 27 is configured to convey the N-type silicon wafer 1 completing the texturing process to the boron diffusion device 3A for further processing.

After the N-type silicon wafer 1 is textured, the N-type silicon wafer 1 is cleaned by the texturing post-cleaning tank 23 and the texturing pickling tank 24. Cleaning agents used are RCA1 (a mixture of hydrogen peroxide, ammonia, and deionized water in a volume ratio of 1:1:5) and RCA2 (a mixture of hydrochloric acid, ammonia, and deionized water in a volume ratio of 1:1:6), to remove one or more combinations of the impurity, a surface damage layer, a cutting line mark, and a metal ion from the surface of the N-type silicon wafer 1, to prepare for a subsequent diffusion process. After the N-type silicon wafer 1 is cleaned and pickled, the N-type silicon wafer 1 is maintained clean by the texturing pre-dehydration tank 25 and the texturing drying tank 26. The texturing unloading apparatus 27 transports the N-type silicon wafer 1 that has completed the texturing process to the boron diffusion device 3A for processing. It may be understood that each apparatus in the above texturing device 2 may be configured based on a specific need of the texturing process, such as increasing or reducing corresponding apparatus, or integrating one or more apparatuses.

After a front side of the N-type silicon wafer 1 is textured, the N-type silicon wafer 1 is transferred by the texturing unloading apparatus 27 to the boron diffusion device 3A for the boron diffusion process, and a boron-doped region 112 is formed on a textured side of the N-type silicon wafer 1 through the boron diffusion process.

As shown in FIG. 5 to FIG. 16, the boron diffusion device 3A includes a first loading and unloading system 31, a first carrier conveying and purifying system 32, and a first furnace tube system 33. The texturing unloading apparatus 27 of the texturing device 2 is connected to the first loading and unloading system 31 of the boron diffusion device 3A.

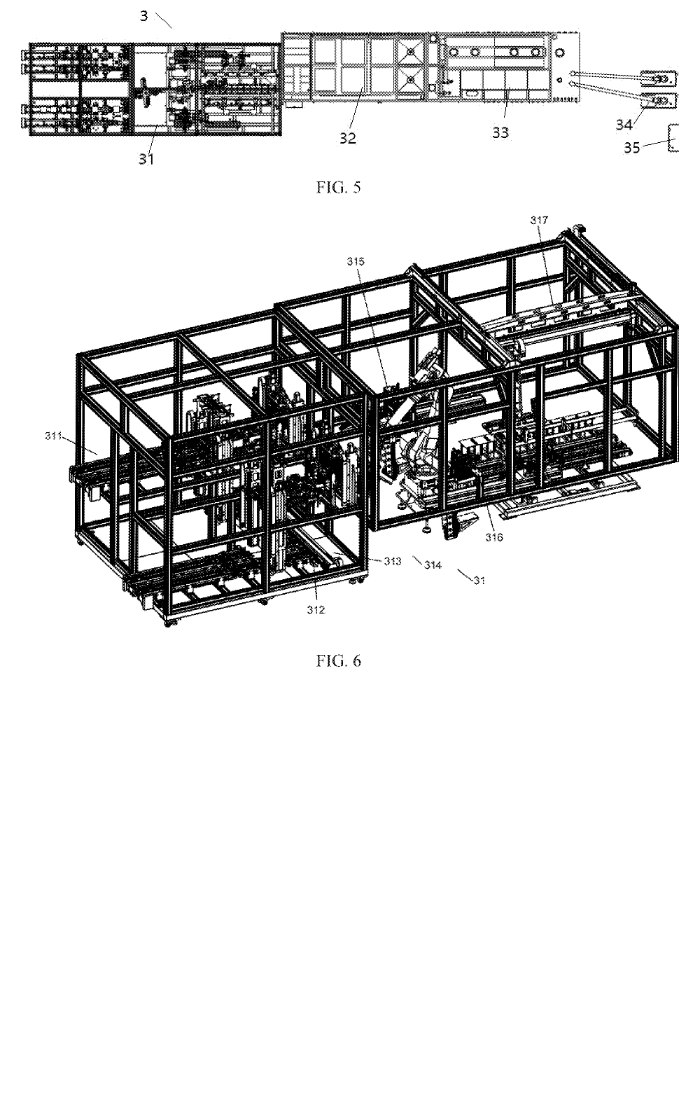

Referring to FIG. 6, the first loading and unloading system 31 includes a first loading wafer-guiding assembly 311, a first unloading wafer-guiding assembly 312, a first wafer-guiding circulation conveying mechanism 313, a first silicon wafer grabbing apparatus 314, a first loading carrying mechanism 315, a first unloading carrying mechanism 316, and a first carrier circulation mechanism 317. The first carrier conveying and purifying system 32 includes a first carrier carrying system 321, a first carrier pushing system 322, a first purifying and cooling system 323, a first transmission system 324, and a first purification table frame 325. The first furnace tube system 33 includes a first furnace tube rack 331 and a first process furnace tube 332. The first process furnace tube 332 includes a boron diffusion furnace tube. The first transmission system 324 is connected to both the first carrier circulation mechanism 317 and the first carrier carrying system 321, and is configured to perform a circulation of a carrier between the first loading and unloading system 31 and the first carrier conveying and purifying system 32. The first carrier pushing system 322 is connected to the first process furnace tube 332, and is configured to perform a circulation of the carrier between the first carrier conveying and purifying system 32 and the first furnace tube system 33. The first process furnace tube 332 include an annealing furnace tube, and is configured to perform an annealing process.

A carrier 319 is configured to be transferred among the first loading and unloading system 31, the first carrier conveying and purifying system 32, and the first furnace tube system 33. The N-type silicon wafer 1 is horizontally placed inside the carrier 319. The carrier 319 includes a carrier limiting plate 3194, and the N-type silicon wafers 1 is horizontally placed in the carrier limiting plate 3194 back to back. The carrier limiting plate 3194 is configured to shield three sides of the N-type silicon wafer 1 to prevent the N-type silicon wafer 1 from being wrap-around plated.

The first loading and unloading system 31 includes a wafer guiding apparatus. The wafer guiding apparatus includes: the first loading wafer-guiding assembly 311, the first unloading wafer-guiding assembly 312, the first wafer-guiding circulation conveying mechanism 313, the first loading carrying mechanism 315, the first unloading carrying mechanism 316 and the first carrier circulation mechanism 317. The first silicon wafer grabbing apparatus 314 is configured to perform operations such as suction, turn-over, movement … of silicon wafer. The first silicon wafer grabbing apparatus 314 includes a six-axis robot 3131 and a silicon wafer grabbing and releasing mechanism 3142. The silicon wafer grabbing and releasing mechanism 3142 is configured to control suction to the N-type silicon wafer 1 and turn-over of the N-type silicon wafer 1. The six-axis robot 3131 is configured to control movement of the N-type silicon wafer 1 through the silicon wafer grabbing and releasing mechanism 3142. The first loading and unloading system 31 includes a silicon wafer loading system and a silicon wafer unloading system. The silicon wafer loading system includes the first loading wafer-guiding assembly 311, the first silicon wafer grabbing apparatus 314, the first loading carrying mechanism 315 and the first carrier circulation mechanism 317. The silicon wafer unloading system includes: the first unloading wafer-guiding assembly 312, the first silicon wafer grabbing apparatus 314, the first unloading carrying mechanism 316 and the first carrier circulation mechanism 317.

The first loading wafer-guiding assembly 311 includes a first loading connection conveying mechanism 3111, a first temporary storage conveying mechanism 3112, a first cassette lifting mechanism 3113, a first cassette conveying mechanism 3114, a first silicon wafer conveying mechanism 3115, a first silicon wafer temporary storage mechanism 3116, and a first wafer receiving mechanism 3117. The first cassette conveying mechanism 3114 is located below the first cassette lifting mechanism 3113. The first unloading wafer-guiding assembly 312 includes a second loading connection conveying mechanism 3121, a second temporary storage conveying mechanism 3122, a second cassette lifting mechanism 3123, a second cassette conveying mechanism 3124, a second silicon wafer conveying mechanism 3125, a second silicon wafer temporary storage mechanism 3126 and a second wafer receiving mechanism 3127, and the second cassette conveying mechanism 3124 is located below the second cassette lifting mechanism 3123. The first wafer-guiding circulation conveying mechanism 313 is both connected to the first cassette conveying mechanism 3114 and the second cassette conveying mechanism 3124. A cassette flows between the first loading wafer-guiding assembly 311 and the first unloading wafer-guiding assembly 312 through the first cassette conveying mechanism 3114, the first wafer-guiding circulation conveying mechanism 313 and the second cassette conveying mechanism 3124.

In the embodiment, the first loading wafer-guiding assembly 311 and the first unloading wafer-guiding assembly 312 are the same in structure. Two sets of the first loading wafer-guiding assembly 311 and the first unloading wafer-guiding assembly 312 are symmetrically distributed. The following first loading wafer-guiding assembly 311 is as an example for explanation. The first loading connection conveying mechanism 3111 adopts an automated guided vehicle (AGV) conveying line, and the first loading connection conveying mechanism 3111 has a length capable of accommodating a plurality of groups of cassettes for simultaneous conveying. Both ends of the first loading connection conveying mechanism 3111 in a conveying direction are fixedly provided with loading blocking cylinders (not shown in the figures). Two sets of loading through-beam sensors (not shown in the figures) are symmetrically and fixedly arranged on two sides, close to the first temporary storage conveying mechanism 3112, of end face of the first loading connection conveying mechanism 3111. The two sets of loading through-beam sensors and the loading blocking cylinders work together to achieve a purpose that the cassettes are sequentially and individually conveyed to the first temporary storage conveying mechanism 3112. In addition, the first loading connection conveying mechanism 3111 is further provided with a plurality of sensors (not shown in the figures), the number of the sensors is consistent with the number of the cassettes that the first loading connection conveying mechanism 3111 may carry at a time, and a distance between adjacent sensors is adjustable. The sensor detects a full or short material status of the cassette, thereby achieving fine control of the number of silicon wafers.

The first cassette lifting mechanism 3113 includes a lifting conveying assembly 31131 and a cassette lifting assembly 31132. The cassette lifting assembly 31132 controls the lifting conveying assembly 31131 to ascend and descend, and a length of the lifting conveying assembly 31131 is matched with a length of a single cassette. The first temporary storage conveying mechanism 3112 conveys a single cassette to the lifting conveying assembly 31131, and the cassette located on the lifting conveying assembly 31131 is fixed by a clamping apparatus, thereby preventing the first silicon wafer conveying mechanism 3115 from deviating when the wafer is taken that affects wafer taking efficiency. In the embodiment, the cassette lifting assembly 31132 adopts a ball screw transmission method to control the lifting conveying assembly 31131 to ascend and descend. The first cassette lifting mechanism 3113 further includes a through-beam sensor configured to detect remaining amount of silicon wafers in the cassette and an orientation sensor (not shown in the figures) configured to detect a orientation of a loading cassette to prevent a reverse placement error when the cassette is conveyed.

The first silicon wafer conveying mechanism 3115 is configured to take the N-type silicon wafer located in the cassette on the first cassette lifting mechanism 3113, and sequentially take the wafer through a lifting function of the lifting conveying assembly 31131 of the first cassette lifting mechanism 3113. The first silicon wafer conveying mechanism 3115 is extended and connected to a first end of the first silicon wafer temporary storage mechanism 3116, and a second end of the first silicon wafer temporary storage mechanism 3116 is extended and connected to the first wafer receiving mechanism 3117. After the N-type silicon wafer is conveyed to the first silicon wafer conveying mechanism 3115, the N-type silicon wafer flows into the first wafer receiving mechanism 3117 sequentially through the first silicon wafer conveying mechanism 3115 and the first silicon wafer temporary storage mechanism 3116. At the same time, the first silicon wafer conveying mechanism 3115 is configured to adjust the N-type silicon wafer, so that the N-type silicon wafer maintains uniformity during a transmission process, inflow of the N-type silicon wafer is facilitated, and inflow efficiency of N-type silicon wafers is improved.

The first wafer receiving mechanism 3117 is provided with a first wafer receiving groove (not shown in the figures). The first wafer receiving mechanism 3117 sequentially guides the silicon wafer conveyed by the first silicon wafer conveying mechanism 3115 and the first silicon wafer temporary storage mechanism 3116 into the first wafer receiving groove.

The first silicon wafer temporary storage mechanism 3116 is located between the first silicon wafer conveying mechanism 3115 and the first wafer receiving mechanism 3117. The first silicon wafer temporary storage mechanism 3116 is fixedly provided with a plurality of temporary storage grooves (not indicated in figures), a length direction of the temporary storage groove is consistent with a silicon wafer conveying direction of the first silicon wafer conveying mechanism 3115, and the adjacent temporary storage grooves are vertically arranged in parallel. The first silicon wafer temporary storage mechanism 3116 serves as a mechanism for temporarily storing the silicon wafer, to avoid a situation where the first wafer receiving groove of the first wafer receiving mechanism 3117 is filled with silicon wafers but the silicon wafer is not taken, a purpose of sequentially importing N-type silicon wafers conveyed on the first silicon wafer conveying mechanism 3115 into the temporary storage grooves is achieved.

The first wafer-guiding circulation conveying mechanism 313 includes a circulation conveying assembly 3131 and a circulation moving assembly 3132. The circulation moving assembly 3132 includes a traversing drive assembly, and the traversing drive assembly adopts a ball screw drive method to drive the circulation conveying assembly 3131 to move relative to the circulation moving assembly 3132. In a moving process, the circulation conveying assembly 3131 is both connected to the first cassette conveying mechanism 3114 and the second cassette conveying mechanism 3124, and a upper end face of the circulation conveying assembly 3131 is located on the same horizontal plane as upper end faces of the first cassette conveying mechanism 3114 and the second cassette conveying mechanism 3124, so as to ensure smooth transition of the cassette.

The first silicon wafer grabbing apparatus 314 includes a six-axis robot 3141 and a silicon wafer grabbing and releasing mechanism 3142. The six-axis robot 3141 controls space movement of the silicon wafer grabbing and releasing mechanism 3142, so that movement of the N-type silicon wafer and taking and placing operations are more flexible, beneficial to improving a speed of taking and placing the N-type silicon wafer and overall automation degree.

The silicon wafer grabbing and releasing mechanism 3142 includes a silicon wafer grabbing and separating mechanism 31421, a silicon wafer grabbing suction cup mechanism 31422, and a silicon wafer grabbing and rotating mechanism 31423. The silicon wafer grabbing suction cup mechanism 31422 includes a suction cup suctioning apparatus and an adjusting apparatus for controlling displacement of the suction cup suctioning apparatus. The silicon wafer grabbing and rotating mechanism 31423 includes a suction cup wafer suctioning apparatus and a rotating apparatus for controlling rotation of the suction cup wafer suctioning apparatus. The silicon wafer grabbing and separating mechanism 31421 controls movement of the silicon wafer through the silicon wafer grabbing suction cup mechanism 31422 and the silicon wafer grabbing and rotating mechanism 31423, the suction cup suctioning apparatus and the suction cup wafer suctioning apparatus control the suction and releasing of the silicon wafer, and the rotating apparatus controls the N-type silicon wafer to turn over.

The first loading carrying mechanism 315 includes a first carrying positioning moving assembly 3151, a first carrying silicon wafer lifting assembly 3152, a first carrying silicon wafer aligning assembly 3153, and a first carrying ion blowing assembly (not shown in the figures). The first unloading carrying mechanism 316 includes a second carrying positioning moving assembly 3160, a second carrying silicon wafer lifting assembly 3161, a second carrying silicon wafer aligning assembly 3162 and a second carrying ion blowing assembly (not shown in the figures). In the embodiment, the first loading carrying mechanism 315 and the first unloading carrying mechanism 316 are the same in structure. Taking the first loading carrying mechanism 315 as an example, the first carrying positioning moving assembly 3151 may be horizontally placed the carrier that is configured to bear the N-type silicon wafer, and enables the first carrying silicon wafer lifting assembly 3152 to pass through interior of the carrier when the first carrying silicon wafer lifting assembly 3152 is in a rising state. The six-axis robot 3141 may drive the silicon wafer grabbing and releasing mechanism 3142 to move the silicon wafer from the first wafer receiving mechanism 3117 to a tooth groove of the first carrying silicon wafer lifting assembly 3152 in the rising state. After the silicon wafer enters the first carrying silicon wafer lifting assembly 3152, the first carrying silicon wafer aligning assembly 3153 may align the silicon wafer from two sides of the silicon wafer. After the silicon wafer is aligned, the first carrying silicon wafer lifting assembly 3152 descends, so that the silicon wafer falls into the carrier. In a process that the silicon wafer enters the carrier, the first carrying ion blowing assembly may facilitate separation of the silicon wafers and the silicon wafer to fall into the tooth groove of the carrier by blowing air between adjacent silicon wafers.

The first carrier circulation mechanism 317 includes a transmission connection conveying assembly 3171, a clamping jaw assembly 3172, and a movement module assembly 3173 for controlling movement of the clamping jaw assembly 3172. The transmission connection conveying assembly 3171 is configured to be capable of bearing a plurality of carriers, for example, the transmission connection conveying assembly 3171 includes a carrier holder for bearing the carrier. The movement module assembly 3173 controls the clamping jaw assembly 3172 with clamped carrier to flow between the carrier holder of the transmission connection conveying assembly 3171 and the first loading carrying mechanism 315.

In order to avoid a problem of wrap-around plating, in the embodiment, a specially-designed carrier is used to support the silicon wafer, and the carrier supports the silicon wafer to enter the first process furnace tube for processing. The carrier 319 includes a carrier top plate 3191, a carrier bottom plate 3192, a carrier support rod 3193 and a carrier limiting plate 3194. The carrier top plate 3191 and the carrier bottom plate 3192 are connected by the carrier support rod 3193, forming a placement space for placing the silicon wafer. The carrier 319 has a simple overall structure and is with a lighter weight, and a load range is expanded as much as possible. The carrier support rod 3193 is provided with carrier clamping plates 31931 at intervals along a length direction, and a clamping plate cavity 31932 is formed between two adjacent carrier clamping plates 31931. The carrier limiting plate 3194 is installed in the clamping plate cavity 3193.

A plurality of groups of carrier support rods 3193 are provided, and are distributed between the carrier top plate 3191 and the carrier bottom plate 3192. The number of the carrier support rods 3193, the shape of the carrier top plate 3191, and the shape of the carrier bottom plate 3192 are all adapted to the silicon wafer. For example, the silicon wafer is rectangular, the entire carrier is formed to be a cuboid, and four carrier support rods 3193 are distributed on four corners of the carrier top plate 3191 and the carrier bottom plate 3192. The carrier clamp plate 31931 is fixedly arranged on opposite surfaces of the two opposite carrier supporting rods 3193 on the left and right sides, and corresponding clamp cavity 31932 on each carrier support rod 3193 is in the same horizontal plane. The carrier limiting plate 3194 is installed in a plurality of sets of clamp cavities 31932 located in the same horizontal plane.

The carrier limiting plate 3194 includes two groups of carrier limiting side plates mounted in the clamping plate cavity 31932, and a carrier limiting connecting plate connected to the two groups of carrier limiting side plates. The carrier limiting side plate and the carrier limiting connecting plate are the same in structure. In an embodiment, the carrier limiting side plate and the carrier limiting connecting plate are integrally formed. In the embodiment, a cross-sectional shape of the clamping plate cavity 31932 in a vertical direction is rectangular, an upper side surface and a lower side surface of the carrier limiting side plate abut against a upper side face and a lower side face of the clamping plate cavity 31932, and a long clamping plate cavity 31932 may ensure installation stability of the carrier limiting side plate. Silicon wafer placing cavities 31941 are fixedly arranged on the carrier limiting side plate and the carrier limiting connecting plate, and corresponding silicon wafer placing cavities 31941 on the carrier limiting side plate and the carrier limiting connecting plate are located on the same horizontal plane. A cross-sectional shape of a silicon wafer placing cavity 31941 in the vertical direction is not limited. In the embodiment, a cross-sectional shape of the silicon wafer placing cavity 31941 is square, the N-type silicon wafer is supported by line contact or surface contact with the silicon wafer placing cavity 31941, and the silicon wafer placing cavity 31941 may accommodate two groups of silicon wafer to be stacking installed.

According to the embodiment, when the silicon wafer is placed in the carrier, three sides of the N-type silicon wafer are shielded by the carrier limiting plate 3194 except for one side of a placing direction of the N-type silicon wafer, so that gas may be effectively prevented from entering a back-to-back contacting surface from a back-to-back N-type silicon wafer gap, thereby effectively avoiding wrap-around plating, and achieving no wrap-around plating or micro-wrap-around plating. In this way, processing of the wrap-around plating layer may be removed, so that a continuous process in the same device system is realized without the need for offline unloading for wet processing.

The carrier top plate 3191 of the carrier is parallel to the carrier bottom plate 3192 of the carrier, providing maximum space for placing carrier plate as much as possible. Because when the carrier top plate 3191 and the carrier bottom plate 3192 of the carrier are not parallel, some space may not be used for horizontal placement of silicon wafers, wasting space and increasing the weight of the carrier.

The carrier is made of a non-conductive, high-temperature resistant, and pressure resistant material. For example, the material is selected as quartz or silicon carbide, in order to reduce the weight of the carrier as much as possible, increase the number of placed carrier plates in the entire carrier, and also conforms to the non-conductive and high-temperature resistance characteristics of the carrier.

In order to ensure stability of the overall structure of the carrier, a carrier connecting shaft 3195 is fixedly arranged between the carrier support rods 3193, and a carrier support plate 31951 is fixedly arranged on the carrier connecting shaft 3195. The carrier support plate 31951 is in the same horizontal plane as a center of gravity of the entire carrier, beneficial for increasing stability of taking and placing the carrier, and deviation of the carrier during transportation is not easy to be caused. A shape of the carrier support plate 31951 may be set based on an actual need, generally rectangle is used, but other shapes may alternatively be used, as long as it is convenient for a mechanical arm to take and place, and support of the carrier holder.

In an implementation process of the first loading and unloading system 31, the cassettes filled with silicon wafers are sequentially conveyed to the first temporary storage conveying mechanism 3112 by the first loading connection conveying mechanism 3111 in a form of individual cassette, and the first temporary storage conveying mechanism 3112 conveys the cassette to the first cassette lifting mechanism 3113. The silicon wafers in the cassette are sequentially conveyed out through the first silicon wafer conveying mechanism 3115, and the silicon wafers located on a conveying line are sequentially fed into the first wafer receiving groove of the first wafer receiving mechanism 3117 through the coordinated operation of the first silicon wafer conveying mechanism 3115 and the first wafer receiving mechanism 3117. The suction cup suctioning apparatus of the silicon wafer grabbing and releasing mechanism 3142 suctions the silicon wafer from the first receiving groove, the six-axis robot 3141 moves the silicon wafer to the first loading carrying mechanism 315, and performs back-to-back lamination of the silicon wafer. Above steps are repeated until the carrier on the first loading carrying mechanism 315 is filled. The carrier filled with silicon wafers is carried to the carrier holder of the transmission connection conveying assembly 3171 through the clamping jaw assembly 3172 controlled by the transmission connection conveying assembly 3171, until the carrier holder is filled with the carriers. The transmission connection conveying assembly 3171 is connected to the first carrier conveying and purifying system 32. The transmission connection conveying assembly 3171 moves the carrier holder to the first carrier conveying and purifying system 32, realizing a movement process of the silicon wafers from the wafer guiding apparatus to the first carrier conveying and purifying system 32. The first carrier conveying and purifying system 32 transfers silicon wafer that has undergone boron diffusion process from the first carrier conveying and purifying system 32 to the transmission connection conveying assembly 3171. The carrier filled with N-type silicon wafers that have undergone boron diffusion process is transported to the first unloading carrying mechanism 316 through the clamping jaw assembly 3172. Reverse circulation is carried out based on the above structure, thereby realizing a movement process of silicon wafers from the first carrier conveying and purifying system 32 to the wafer guiding apparatus.

The first carrier conveying and purifying system 32 includes a first carrier carrying system 321, a first carrier pushing system 322, a first purifying and cooling system 323, a first transmission system 324, and a first purification table frame 325. The first carrier carrying system 321, the first carrier pushing system 322 and the first transmission system 324 are installed inside the first purification table frame 325. The first purifying and cooling system 323 is located outside the first purification table frame 325, and is configured to purify a gas of the first carrier conveying and purifying system 32. The first transmission system 324 is configured to transfer a carrier loaded with an unprocessed N-type silicon wafer located in the first loading and unloading system 31 to the first carrier carrying system 321, and transfer a carrier loaded with a processed N-type silicon wafer to the first loading and unloading system 31, so as to perform a carrier interaction between the first carrier carrying system 321 and the first loading and unloading system 31. The first carrier carrying system 321 is configured to move the carrier loaded with the unprocessed N-type silicon wafer to the first carrier pushing system 322. The first carrier pushing system 322 is configured to move the carrier loaded with the unprocessed N-type silicon wafer to the first furnace tube system 33 for processing. The first carrier pushing system 322 is further configured to move out the carrier loaded with the processed N-type silicon wafer and move the carrier loaded with the processed N-type silicon wafer to the first transmission system 324 through the first carrier carrying system 321.

That is to say, the first transmission system 324 is configured to perform the carrier interaction between the first carrier carrying system 321 and the first loading and unloading system 31. Specifically, on the one hand, the first carrier carrying system 321 moves the carrier loaded with unprocessed N-type silicon wafers to the first carrier pushing system 322, and the first pushing carrier system 322 moves the carrier loaded with unprocessed N-type silicon wafers to the first furnace tube system 33 for boron diffusion process; on the other hand, the first carrier pushing system 322 moves the carrier loaded with the processed N-type silicon wafer out and moves the carrier loaded with the processed N-type silicon wafer to the first transmission system 324 through the first carrier carrying system 321.

The first carrier carrying system 321 includes a carrier carrying column 3211, a carrier carrying head 3212, and a Z-axis transmission structure 3214. The carrier carrying head 3212 is movably arranged on the carrier carrying column 3211 through the Z-axis transmission structure 3214. The carrier carrying head 3212 includes a first-stage arm 32121, a second-stage arm 32122, a first X-axis transmission structure 32123, a second X-axis transmission structure 32124, and a carrier carrying mechanical gripper 3213. The first-stage arm 32121 and the second-stage arm 32122 are movably connected through the first X-axis transmission structure 32123. The carrier carrying mechanical gripper 3213 is movable arranged on the second-stage arm 32122 through the second X-axis transmission structure 32124. The first X-axis transmission structure 32123 includes a first X-axis servo motor 32125, and the first X-axis servo motor 32125 is located on outer side of the first-stage arm 32121. The carrier carrying mechanical gripper 3213 is configured to support and lift the carrier holder.

The first carrier carrying system 321 further includes a temporary storage carrier carrying mechanical hand 3215 fixed on the carrier carrying column 3211. The temporary storage carrier carrying mechanical hand 3215 is correspondingly arranged on two carrier carrying columns 3211, and the temporary storage carrier carrying mechanical hand 3215 is configured to temporarily store a carrier holder. In the example, six temporary storage carrier carrying mechanical hands 3215 may be arranged on one carrier carrying column 3211. Therefore, maximum number of carrier holders that may be temporarily stored simultaneously on two carrier carrying columns 3211 is six. The first carrier moving system 321 further includes a photoelectric limit sensor 3216. The photoelectric limit sensor 3216 is arranged on the carrier carrying column 3211. and may be configured to sense positions of the carrier carrying head 3212, the first-stage arm 32121, the second-stage arm 32122, and the carrier carrying mechanical gripper 3213, and accuracy of position control of the apparatus is improved.

The first carrier carrying system 321 controls movement of the carrier carrying head 3212 in a Z-axis direction by arranging the Z-axis transmission structure 3214 on the carrier carrying column 3211. Movement of the second-stage arm 32122 and the carrier carrying mechanical gripper 3213 in an X-axis direction is controlled by arranging the first X-axis transmission structure 32123 and the second X-axis transmission structure 32124 of the carrier carrying head 3212.

During an implementation of the first carrier carrying system 321, the first transmission system 324 acquires the carrier holder from the first loading and unloading system 31 and transmits the carrier holder, and the carrier carrying mechanical gripper 3213 moves the carrier holder from the first transmission system 324 to the first carrier pushing system 322. In a continuous production, the temporary storage carrier carrying mechanical hand 3215temporarily stores the carrier holder.

The first carrier pushing system 322 includes a carrier pushing conveying mechanism 3221, a carrier pushing paddle 3222, and a carrier pushing furnace door 3223. The carrier pushing paddle 3222 is connected to the carrier pushing furnace door 3223, and moves synchronously with the carrier pushing furnace door 3223. The carrier pushing paddle 3222 is configured to support and bear the carrier holder and the carrier 319. The carrier 319 is loaded with the silicon wafer, and the carrier pushing conveying mechanism 3221 drives the carrier pushing paddle 3222 to move back and forth to control the carrier support and carrier 319 to enter and exit the first process furnace tube 332.

A sliding direction of the carrier pushing conveying mechanism 3221 is consistent with an axial direction of the first process furnace tube 332.

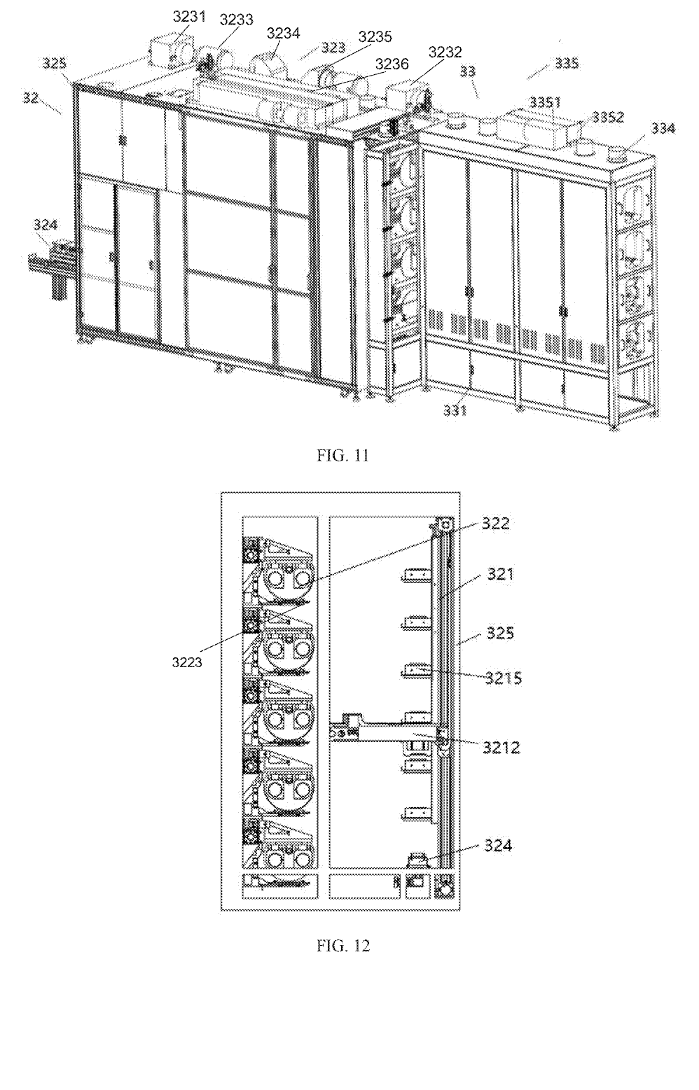

The first purifying and cooling system 323 includes a purifying apparatus and a cooling apparatus. The purifying apparatus includes a first filter 3231, a second filter 3232, a purification fan 3233, a first air inlet 3234, and a second air inlet 3235 (as shown in FIG. 11). The first filter 3231, purification fan 3233, first air inlet 3234, second air inlet 3235 and second filter 3232 are horizontally arranged above the first purification table frame 325, and are connected through a pipeline. According to the embodiment, the first filter 3231 and the second filter 3232 uses an air filter element for purifying, adopting a physical purification method. The number of the first filter 3231 and the second filter 3232 are at least one group. According to the embodiment, the number of the first filter 3231 and the second filter 3232 are two groups, and the first filter 3231 and the second filter 3232 are both connected to internal space of the first purification table frame 325 through a gas pipeline structure (not shown in the figures). The first filter 3231 and the second filter 3232 introduce air outside the first purification table frame 325 that has been purified by the purification fan 3233 into interior of the first purification table frame 325. Since the silicon wafer process requires a clean environment, the gas entering the frame of the first carrier conveying and purifying 32 needs to be filtered and purified first. In the embodiment, a purpose of arranging the first filter 3231 and the second filter 3232 as two groups is to ensure uniform airflow inside the first purification table frame 325, avoid occurrence of large airflow on one side and small airflow on the other side, and ensure uniform heat dissipation of the silicon wafer. By arranging the first filter 3231 and the second filter 3232 to introduce purified cold air, internal cooling of the first purification table frame 325 may be greatly achieved without introducing pollution.

The purification fan 3233 as well as the first air inlet 3234 and the second air inlet 3235 are designed to ensure air circulation inside the first purification table frame 325. The purification fan 3233 is connected to the first air inlet 3234 and the second air inlet 3235 separately. The first air inlet 3234 and the second air inlet 3235 are respectively equipped with an airflow guiding outlet (not shown in the figures). The guiding outlet is disposed on side of the first air inlet 3234 and the second air inlet 3235, in order to prevent dust from falling into the interior of the first purification table frame 325 along the first air inlet 3234 and the second air inlet 3235 when the first air inlet 3234 and the second air inlet 3235 are not in operation. The gas outside the first purification table frame 325 may be drawn into the interior of the first purification table frame 325 through the first air inlet 3234 and the second air inlet 3235. The first air inlet 3234 and the second air inlet 3235 with the first filter 3231 and the second filter 3232 achieves airflow flow inside and outside the first purification table frame 325.

The cooling apparatus includes the first air inlet 3234, the second air inlet 3235, the air outlet, and the purification fan 3233, and the air outlet is located inside the first carrier conveying and purifying system 32. In order to improve cooling efficiency inside the first purification table frame 325, the first air inlet 3234, the second air inlet 3235, the air outlet, and the purification fan 3233 are used to form an air cooling method. The embodiment may alternatively adopt a combination of an air cooling apparatus and a water cooling apparatus. The water cooling apparatus includes a water cooling disc 3236 and a water cooling pipeline (not shown in the figures). The water cooling disc 3236 and the water cooling pipeline form a closed circulating circuit. One side of the water cooling disc is equipped with a water cooling disc fan, and the water cooling disc fan provided on the water cooling disc is configured to achieve rapid cooling of the water cooling disc. Hot air inside the first carrier conveying and purifying system 32 may be pumped up and cooled by the water cooling disc, and then the cooled hot air is discharged outside the first carrier conveying and purifying system 32 or inside the first carrier conveying and purifying system 32 for internal circulation. When the hot air flow inside the first carrier conveying and purifying system 32 passes through the water cooling disc, the hot air flow exchanges heat with a heat dissipation fin set on the water cooling disc coil, so that temperature of the hot air flow decreases. The cooled hot airflow may be directly discharged to the outside or to the inside. The heat dissipation fin is made of aluminum or copper material. In the embodiment, the water cooling disc 3236 is further provided with a water inlet and outlet pipe. The water inlet and outlet pipe is vertically disposed at the top of the first purification table frame 325, and is connected to the water cooling disc 3236 through a valve and a pipeline. The water cooling pipeline may be disposed above, on one side, or inside the purification table frame 325, or any combination thereof. In the embodiment, the water cooling pipeline is disposed above, on sides, and inside the first purification table frame 325, and rapid cooling of the interior of the first purification table frame 325 is achieved through water cooling combined with air cooling. In order to improve water cooling efficiency, specific coolant may alternatively be used to replace the water medium.

The first transmission system 324 includes a transmission mechanism 3241 and a transmission frame 3242. The transmission mechanism 3241 is located on the transmission frame 3242 and is supported by the transmission frame 3242. The transmission mechanism 3241 includes a transmission drive assembly 3240, a transmission belt 3247, and a transmission tension assembly. The transmission mechanism 3241 transmits a carrier support plate assembly by means of the transmission belt 3247. The transmission tension assembly controls tension of the transmission belt 3247. The carrier support plate assembly is configured to bear the carrier holder. The carrier holder is configured to bear the carrier.

During a transmission process of the first transmission system 324, the transmission drive assembly 3240 of the transmission mechanism 3241 controls transmission of the transmission belt 3247. The transmission of the transmission belt 3247 drives the carrier holder located on the carrier support plate assembly to move, thereby transferring a carrier loaded with a processed silicon wafer to the first loading and unloading system 31, transferring a carrier the loaded with an unprocessed silicon wafer located on the first loading and unloading system 31 to the first carrier carrying system 321, and ensuring that the transmission mechanism 3241 achieves stable and reliable transmission of the carrier.

The first furnace tube system 33 includes a first furnace tube rack 331 and a first process furnace tube 332. The first process furnace tube 332 is horizontally mounted on the first furnace tube rack 331, and an opening of the first process furnace tube 332 faces the first carrier pushing system 322. The first carrier pushing system 322 moves the carrier 319 to the first process furnace tube 332 for processing through the carrier pushing conveying mechanism 3221 and the carrier pushing paddle 3222, or conveys the carrier 319 loaded with the processed silicon wafer out of the first process furnace tube 332. When the carrier pushing paddle 3222 pushes the carrier 319 as far as possible into the first process furnace tube 332, the carrier pushing furnace door 3223 may seal the opening of the first process furnace tube 332, so that a cavity isolated from the outside is formed inside the first process furnace tube 332. A tail of the first process furnace tube 332 is provided with a gas conveying apparatus 333 connected to the interior of the first process furnace tube. The gas conveying apparatus 333 regulates internal pressure of the first process furnace tube 332. Generally, before introducing a reaction gas, the furnace needs to be evacuated to form a vacuum furnace state. Then, based on an actual reaction need, a gas is introduced for reaction, catalysis, or protection.

According to the embodiment, the boron diffusion device 3A is configured to perform a boron diffusion process of the N-type silicon wafer 1.

The first furnace tube system 33 includes the first process furnace tubes 332. The first process furnace tube 332 corresponds to the first carrier carrying system 321. The first process furnace tubes 332 are arranged in parallel, either vertically or horizontally, or both vertically and horizontally to form a combination of rows and columns to increase production. The first process furnace tube 332 and the first carrier carrying system 321 can both work independently to achieve continuous production. The first process furnace tube 332 may include a boron diffusion process furnace tube. The boron diffusion process furnace tube is configured to perform a boron diffusion process of the N-type silicon wafer, so that consumption of process device and labor is saved, and transshipment damage of the silicon wafer is reduced. The first furnace tube system 33 is designed with multiple sets of tubes arranged side by side, so that synchronous and orderly operation of loading and unloading of the first loading and unloading system 31 and the silicon wafer process may be achieved. During a reacting process of one furnace, unloading of a previous furnace and loading of a subsequent furnace may be carried out, so that continuous high-yield production is achieved. In the embodiment, the first furnace tube system 33 further includes a gas source cabinet 35, used to perform the boron diffusion process.

In some other embodiments, the heat treatment system 3 may include a LPCVD process tube and the annealing process tube. The LPCVD process tube and the annealing process tube may alternatively be combined with other components to form other device, respectively. As an example, the LPCVD process tube may be combined with other components to form an independent LPCVD device. The annealing process tube may be combined with other components to form an independent annealing process device.

The gas conveying apparatus 333 includes a reaction gas conveying apparatus and a tail gas treatment apparatus. The reaction gas conveying apparatus introduces process gas to the first process furnace tube 332. The tail gas treatment apparatus is configured to assist in unloading gas or balancing gas pressure.

The first furnace tube system 33 further includes a furnace cavity air cooling apparatus 335 and a first furnace tube rack cooling apparatus 334. The furnace cavity air cooling apparatus 335 includes a first furnace tube rack air cooling disk 3351. The first furnace tube rack air cooling disk 3351 is arranged on the top of the first furnace tube rack 331. Multiple groups of air cooling exhaust vents 3352 are further arranged at the top of the first furnace tube rack 331. Each group of air cooling exhaust vents 3352 corresponds to an exhaust fan. The exhaust fan is driven by the purification fan. An upward ventilation pipe is disposed on the first furnace tube rack 331 where each group of the first process furnace tubes 332 is located. The ventilation pipe is connected to the first furnace tube rack air cooling disk 3351 from the side of each group of the first process furnace tubes 332. The furnace cavity air cooling apparatus 335 discharges heat of the first furnace tube rack 331, and the first furnace tube rack cooling apparatus 334 reduces heat of discharged air, significantly reducing thermal radiation effect of high temperature of the first process furnace tubes on the furnace tube environment during apparatus operation, so that the process temperature is prevented from being too high and affecting a normal operation of an electrical apparatus, and a production process cycle of the silicon wafer is greatly shortened, thereby improving production efficiency. Moreover, a combination of air cooling and water cooling methods is adopted, a pipeline structure is connected to the interior of the first process furnace tube, a problem of impact of the heating of the first process furnace tube on the silicon wafer production process is solved, so that a process cooling speed is accelerated, a process yield is improved, and a failure rate of electrical apparatus is reduced.

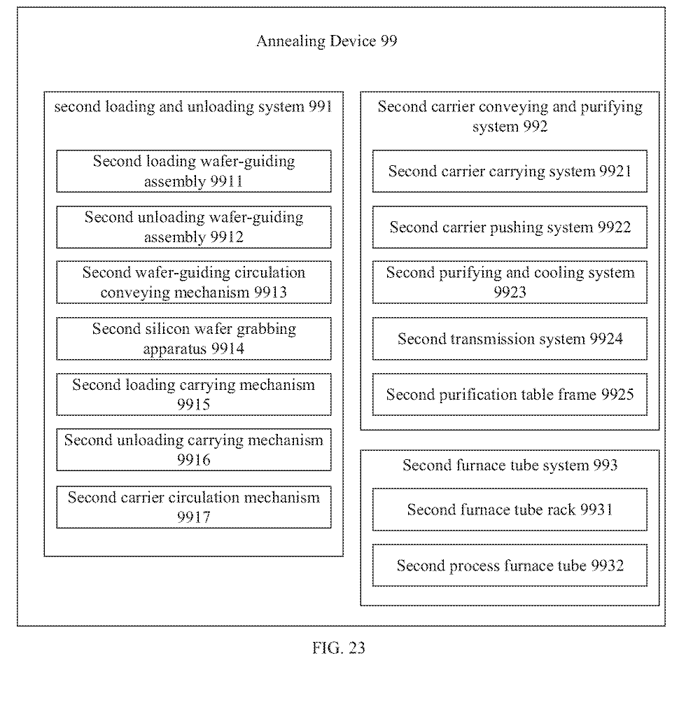

As shown in FIG. 23, the annealing device 99 includes a second loading and unloading system 991, a second carrier conveying and purifying system 992, and a second furnace tube system 993. The second loading and unloading system 991 includes a second loading wafer-guiding assembly 9911, a second unloading wafer-guiding assembly 9912, a second wafer-guiding circulation conveying mechanism 9913, a second silicon wafer grabbing apparatus 9914, a second loading carrying mechanism 9915, a second unloading carrying mechanism 9916 and a second carrier circulation mechanism 9917. The second carrier conveying and purifying system 992 includes a second carrier carrying system 9921, a second carrier pushing system 9922, a second purifying and cooling system 9923, a second transmission system 9924 and a second purification table frame 9925. The second furnace tube system 993 includes a second furnace tube rack 9931 and a second process furnace tube 9932. The second transmission system 9924 is connected to both the second carrier circulation mechanism 9917 and the second carrier carrying system 9921, and is configured to perform a circulation of a carrier between the second loading and unloading system 991 and the second carrier conveying and purifying system 992. The second carrier pushing system 9922 is connected to the second process furnace tube 9932, and is configured to perform a circulation of the carrier between the second carrier conveying and purifying system 992 and the second furnace tube system 993. The second process furnace tube 9932 includes an annealing furnace tube, and is configured to perform the annealing process.

The carrier 319 is further configured to be transferred among the second loading and unloading system 991, the second carrier conveying and purifying system 992, and the second furnace tube system 993.

The second loading and unloading system 991 includes a wafer guiding apparatus. The wafer guiding apparatus includes: the second loading wafer-guiding assembly 9911, the second unloading wafer-guiding assembly 9912, the second wafer-guiding circulation conveying mechanism 9913, the second silicon wafer grabbing apparatus 9914, the second loading carrying mechanism 9915, the second unloading carrying mechanism 9916 and the second carrier circulation mechanism 9917. The second silicon wafer grabbing apparatus 9914 is configured to perform operations such as suction, turn-over, movement … of silicon wafer. The second silicon wafer grabbing apparatus 9914 includes a six-axis robot and a silicon wafer grabbing and releasing mechanism. The silicon wafer grabbing and releasing mechanism is configured to control suction to the N-type silicon wafer 1 and turn-over of the N-type silicon wafer 1. The six-axis robot is configured to control movement of the N-type silicon wafer 1 through the silicon wafer grabbing and releasing mechanism. The second loading and unloading system 991 includes a silicon wafer loading system and a silicon wafer unloading system. The silicon wafer loading system includes the second loading wafer-guiding assembly 9911, the second silicon wafer grabbing apparatus 9914, the second loading carrying mechanism 9915 and the second carrier circulation mechanism 9917. The silicon wafer unloading system includes: the second unloading wafer-guiding assembly 9912, the second silicon wafer grabbing apparatus 9914, the second unloading carrying mechanism 9916 and the second carrier circulation mechanism 9917.

The second carrier conveying and purifying system 992 includes a second carrier carrying system 9921, a second carrier pushing system 9922, a second purifying and cooling system 9923, a second transmission system 9924, and a second purification table frame 9925. The second carrier carrying system 9921, the second carrier pushing system 9922, and the second transmission system 9924 are installed inside the second purification table frame 9925. The second purifying and cooling system 9923 is located outside the second purification table frame 9925, and is configured to purify a gas of the second carrier conveying and purifying system 992. The second transmission system 9924 is configured to transfer a carrier loaded with an N-type silicon wafer 1 not subjected to the annealing process located in the second loading and unloading system 991 to the second carrier carrying system 9921, and transfer a carrier loaded with an N-type silicon wafer subjected to the annealing process to the second loading and unloading system 991, so as to perform a carrier interaction between the second carrier carrying system 9921 and the second loading and unloading system 991. The second carrier carrying system 9921 is configured to move the carrier loaded with the N-type silicon wafer not subjected to the annealing process to the second carrier pushing system 9922. The second carrier pushing system 9922 is configured to move the carrier loaded with the N-type silicon wafer 1 not subjected to the annealing process to the second furnace tube system 993 for the annealing process. The second carrier pushing system 9922 is further configured to move out the carrier loaded with the N-type silicon wafer 1 subjected to the annealing process and move the carrier loaded with the N-type silicon wafer 1 subjected to the annealing process to the second transmission system 9924 through the second carrier carrying system 9921.

That is to say, the second transmission system 9924 is configured to perform the carrier interaction between the second carrier carrying system 9921 and the second loading and unloading system 991. Specifically, on the one hand, the second carrier carrying system 9921 moves the carrier loaded with the N-type silicon wafer not subjected to the annealing process to the second carrier pushing system 9922, and the second carrier pushing system 9922 moves the carrier loaded with the N-type silicon wafer not subjected to the annealing process to the second furnace tube system 993 for the annealing process; on the other hand, the second carrier pushing system 9922 moves the carrier loaded with the N-type silicon wafer subjected to the annealing process out and moves the carrier loaded with the N-type silicon wafer subjected to the annealing process to the second transmission system 9924 through the second carrier carrying system 9921.

The second furnace tube system 993 includes a second furnace tube rack 9931 and a second process furnace tube 9932. The second process furnace tube 9932 is horizontally mounted on the second furnace tube rack 9931, and an opening of the second process furnace tube 9932 faces the second carrier pushing system 9922. The second carrier pushing system 9922 moves the carrier 319 to the second process furnace tube 9932 for the annealing process, or moves the carrier 319 loaded with the silicon wafer subjected to the annealing process out of the second process furnace tube 9932.

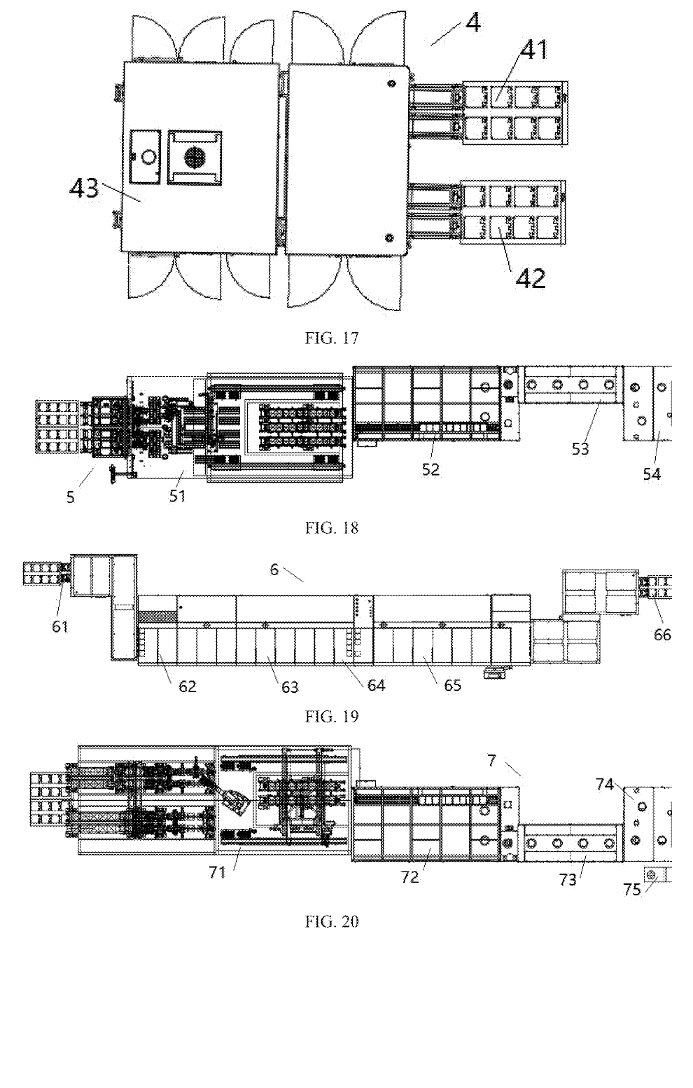

The production line 10 for producing the solar cell further includes a laser doping device 4. The laser doping device 4 is configured to perform laser local boron doping on a front side of the N-type silicon wafer 1 to form a boron heavily doped region, and perform laser local phosphorus doping on the back side of the N-type silicon wafer 1 to form a phosphorus heavily doped region. As shown in FIG. 17, the N-type silicon wafer 1 after boron diffusion is transported to the laser doping device 4. The laser doping device 4 includes a laser doping loading end 41, a laser processing cavity 43, and a laser unloading end 42. The first loading and unloading system 31 of the boron diffusion device 3A is connected to the laser doping loading end 41 of the laser doping device 4. A laser process device is provided in the laser processing cavity 43. The laser process device is configured to perform laser grooving on a textured surface, perform front laser local doping on a grooving region of an N-type silicon wafer 1 after boron diffusion to form the boron heavily doped region 113. The laser process device includes a boron source. The boron source provides boron for the boron heavily doped region 113. The N-type silicon wafer 1 after laser local boron doping is transported from the laser processing cavity 43 to the laser unloading end 42.

The laser doping device 4 is further configured to perform laser grooving on a surface without being textured, perform front laser local doping on a grooving region of an N-type silicon wafer 1 after phosphorus diffusion to form the phosphorus heavily doped region 123. The laser process device includes a phosphorus source. The N-type silicon wafer 1 after laser local phosphorus doping is transported from the laser processing cavity 43 to the laser unloading end 42.

It can be understood that if the laser doping device 4 is required to perform local laser boron doping on the front side and perform local laser phosphorus doping on the back side, the solar cell production line may include two laser doping devices 4.

In some other embodiments, the production line 10 for producing the solar cell further includes an oxidation system 5. The oxidation system 5 is configured to perform an oxidation process of the N-type silicon wafer 1 to protect the boron heavily doped region and the phosphorus heavily doped region. As shown in FIG. 18, the oxidation system 5 includes an oxidation loading and unloading apparatus 51, an oxidation purification table 52, an oxidation furnace body 53 and an oxidation gas cabinet 54. The laser unloading end 42 of the laser doping device 4 is connected to the oxidation loading and unloading apparatus 51 of the oxidation system 5. The N-type silicon wafer 1 after laser local boron doping is conveyed to the oxidation system 5, and the oxidation system 5 processes the N-type silicon wafer 1 to protect the boron heavily doped region 113. The N-type silicon wafer 1 after laser local phosphorus doping is conveyed to the oxidation system 5, and the oxidation system 5 processes the N-type silicon wafer 1 to protect the phosphorus heavily doped region 123.

Specifically, the oxidation loading and unloading apparatus 51 is configured to transfer a non-oxidized deposited N-type silicon wafer 1 to the oxidation furnace body 53 for an oxidation deposition process or to transfer an oxidized deposited N-type silicon wafer 1 to a next process. The oxidation purification table 52 has a structure similar to the structure of the first carrier conveying and purifying system 32 and serves a similar function. The oxidation furnace body 53 has a structure similar to the structure of the first furnace tube system 33, and is configured to perform the oxidation deposition process of the N-type silicon wafer 1. The oxidation gas cabinet 54 provides source gas or liquid for the oxidation deposition process of the oxidation furnace body 53. Optionally, the oxidation system 5 may include a low pressure horizontal oxidation system. Optionally, an N-type silicon wafer 1 after laser local boron doping may be obtained by performing laser local boron doping on an N-type silicon wafer 1 by using the laser doping device. Optionally, an N-type silicon wafer 1 after laser local phosphorus doping may be obtained by performing laser local phosphorus doping on an N-type silicon wafer 1 by using the laser doping device.

In the embodiment, the etching device 6 is further configured to perform an alkali polishing process of the N-type silicon wafer 1. As shown in FIG. 19, the etching device 6 includes an alkali polishing and etching loading apparatus 61, an alkali polishing and etching protection apparatus 62, an alkali polishing and etching performing apparatus 63, an alkali polishing and etching alkali washing apparatus 64, an alkali polishing and etching pickling apparatus 65 and an alkali polishing and etching unloading apparatus 66. The alkali polishing and etching loading apparatus 61 of the etching device 6 is connected to the oxidation loading and unloading apparatus 51 of the oxidation system 5. An N-type silicon wafer 1 is conveyed to the etching device 6 for cleaning and etching, to remove a boro silicate glass (BSG) layer on a front surface of the N-type silicon wafer 1, chemically polish a back surface of the N-type silicon wafer 1, and solve a problem that laser ablation is easy to form a dead layer or a damaged layer. The etching device 6 can further be configured to clean and etch the N-type silicon wafer 1, so as to remove a phospho silicate glass (PSG) and a wrap-around plating on the surface of N-type silicon wafer 1. It is understandable that production line 10 for producing the solar cell can include two etching devices 6, one etching device 6 can be configured for removing the BSG layer and chemically polishing, and the other etching device 6 can be configured for removing the PSG.

In some other embodiments, the alkali polishing and etching loading apparatus 61 is connected to the oxidation system 5.

In some other embodiments, the heat treatment system 3 may further include a LPCVD device. The alkali polishing and etching unloading apparatus 66 is connected to the LPCVD device. An alkali polished and etched N-type silicon wafer 1 is transmitted to the LPCVD device for a LPCVD process. During the LPCVD process, a tunneling silicon oxide passive film is generated on the N-type silicon wafer 1, and intrinsic polysilicon is deposited on the tunneling oxide layer.

In some other embodiments, the production line 10 for producing the solar cell further includes a phosphorus diffusion device 7. As shown in FIG. 20, the phosphorus diffusion device 7 includes a phosphorus diffusion loading and unloading system 71, a phosphorus diffusion purification table 72, a phosphorus diffusion furnace cabinet 73, a phosphorus diffusion gas cabinet 74 and a phosphorus diffusion phosphorus source cabinet 75.

In some other embodiments, the LPCVD device is connected to the phosphorus diffusion loading and unloading system 71 of the phosphorus diffusion device 7. A LPCVD processed N-type silicon wafer 1 is conveyed to the phosphorus diffusion device 7 for phosphorus diffusion. In the embodiment, the phosphorus diffusion device 7 uses a stepped phosphorus diffusion method to perform multiple phosphorus diffusion operations on a back side of the N-type silicon wafer 1, so that multiple layers of phosphorus-doped region 122 is formed on the back side of the N-type silicon wafer 1. After phosphorus diffusion, a post-oxidation treatment is performed, so that a phosphorus-doped layer, which is also referred to as a phosphorus-rich layer, is formed on the back side of the N-type silicon wafer 1. And through the process, concentration of the PSG on an outer surface of N-type silicon wafer is increased, and a PSG layer is formed.

In the embodiment, the PECVD device 98 is configured to perform a PECVD process of N-type silicon wafer 1 to form an oxide layer 121 and a phosphorus-doped polycrystalline silicon layer (that is, the aforementioned phosphorus-doped layer) on the back side of N-type silicon wafer 1.

In one possible implementation of the present embodiment, the PECVD device 98 is configured to perform the PECVD process on the N-type silicon wafer 1, so as to form an oxide layer 121 and a doped amorphous silicon layer on the back side of the N-type silicon wafer 1. In the implementation, the N-type silicon wafer 1 is further subjected to a phosphorus diffusion process through the phosphorus diffusion device 7, so that a doped amorphous silicon layer is crystallized to form a doped polycrystalline silicon layer (that is, the aforementioned phosphorus-doped layer).

In the present embodiment, the PECVD device is connected to the annealing device 99. A phosphorus-doped amorphous silicon layer can be converted into a phosphorus-doped polycrystalline silicon layer through the annealing process. The phosphorus-doped polycrystalline silicon layer may also be referred to as the aforementioned phosphorus-doped layer.

In a possible implementation of this embodiment, a structure of the PECVD device 98 is similar to that of the boron diffusion device 3A. The PECVD device 98 also includes a corresponding loading and unloading system, a carrier conveying and purifying system, and a furnace tube system. The furnace tube system of PECVD device 98 is provided with a PECVD furnace tube.

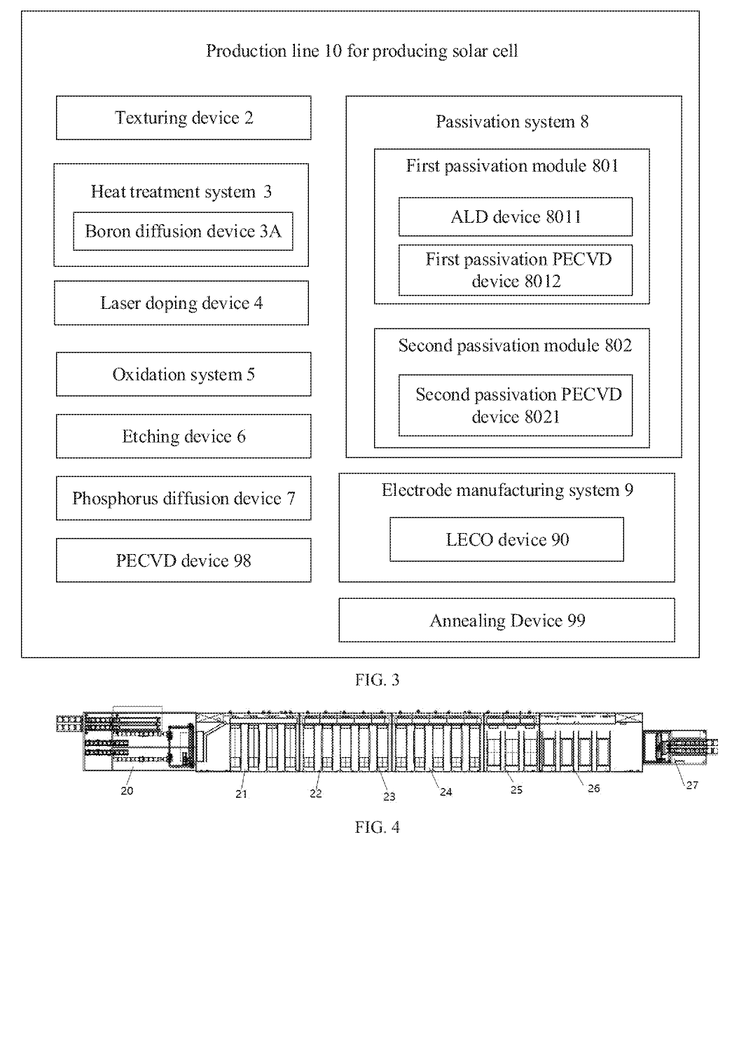

As shown in FIG. 3, the passivation system 8 includes a first passivation module 801 and a second passivation module 802. The first passivation module 801 is configured to perform the passivation layer process. Through the passivation layer process, a passivation layer 111 may be deposited on the surface of the N-type silicon wafer 1 by the passivation system 8. A material of the passivation layer 111 is not limited here. For example, a material of the passivation layer 111 may be aluminum oxide. The passivation layer 111 may include at least one of Si_{y}Nₓ, Si_{z}NₓO_{y}, SiO₂, and other similar materials.The first passivation module 801 includes an atomic layer deposition (ALD) device 8011 or a first passivation PECVD device 8012. The second passivation module 802 is configured to perform the front film process and the back film process. The front film process is used to deposit a first anti-reflection layer 110 on the front side of the N-type silicon wafer 1, and the back film process is used to deposit a second anti-reflection layer 120 on the back side of the N-type silicon wafer 1. Materials of the first anti-reflection layer 110 and the second anti-reflection layer 120 are not limited here. For example, materials of the first anti-reflection layer 110 and the second anti-reflection layer 120 both may be at least one of Si_{y}Nₓ, Si_{z}NₓO_{y} and SiO₂. The second passivation module 802 includes a second passivation PECVD device 8021.

In an implementation, the first passivation module 801 and the second passivation module 802 are arranged in the same PECVD device. That is to say, the passivation system 8 includes a PECVD device for simultaneously implementing functions of the first passivation module 801 and the second passivation module 802, that is, the first passivation PECVD device 8012 and the second passivation PECVD device 8021 are a same PECVD device.

In some embodiments, as shown in FIG. 20, the passivation system 8 includes a passivation loading and unloading apparatus 81, a passivation purification table 82, a passivation furnace body 83, a passivation gas cabinet 84 and a passivation vacuum pump 85. Exemplarily, the passivation loading and unloading apparatus 81, the passivation purification table 82, the passivation furnace body 83, the passivation gas cabinet 84 and the passivation vacuum pump 85 are applied to one or more of the ALD device 8011, the first passivation PECVD device 8012 and the second passivation PECVD device 8021.

In some embodiments, the passivation layer 111 is disposed on one of the front side and the back side of the N-type silicon wafer 1. For example, as shown in FIG. 3, the passivation layer 111 is disposed only on the front side of the N-type silicon wafer 1. In other embodiments, the passivation layer 111 is disposed on both the front side and the back side of the N-type silicon wafer 1.

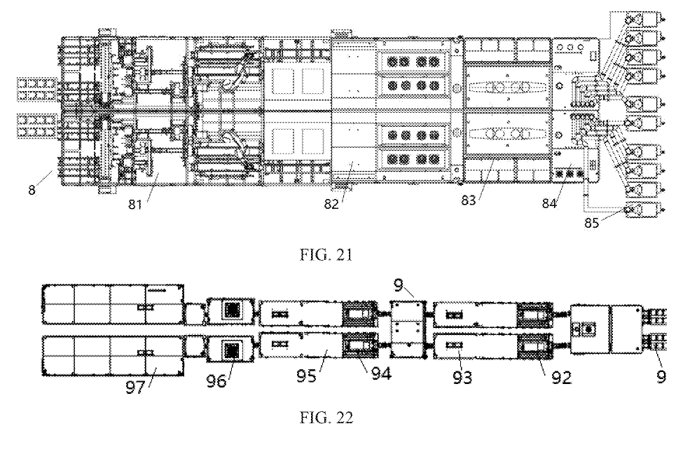

As shown in FIG. 21, the electrode manufacturing system 9 includes an electrode manufacturing loading apparatus 91, a first electrode manufacturing apparatus 92, an electrode manufacturing drying apparatus 93, a second electrode manufacturing apparatus 94, an electrode manufacturing sintering apparatus 95, an electrode manufacturing detecting apparatus 96, and an electrode manufacturing sorting apparatus 97. The passivation loading and unloading apparatus 81 of the passivation system 8 is connected to the electrode manufacturing loading apparatus 91. The passivation system 8 is further configured to convey an N-type silicon wafer 1 processed by the passivation system 8 to the electrode manufacturing loading apparatus 91. The electrode manufacturing system 9 is configured to perform a preparation process of electrodes on two sides of the N-type silicon wafer to form the solar cell. The electrode manufacturing loading apparatus is configured to receive the N-type silicon wafer processed by the passivation system. The first electrode manufacturing apparatus 92 is configured to prepare a back electrode 12 on the N-type silicon wafer. The second electrode manufacturing apparatus 94 is configured to prepare a front electrode 11 on the N-type silicon wafer 1. The electrode manufacturing sintering apparatus 95 is configured to sinter the N-type silicon wafer after the electrodes are manufactured into a finished solar cell. The electrode manufacturing detecting apparatus 96 and the electrode manufacturing sorting apparatus 97 are configured to remove an unqualified finished solar cell from the finished solar cell. The electrode manufacturing process may include a screen printing process or an imprinting process. The front electrode 11 includes a plurality of main grids and a plurality of fine grids. The back electrode includes a plurality of main grids and a plurality of fine grids. Exemplarily, the electrode manufacturing sintering apparatus 95 is further configured to perform a light injection process of the N-type silicon wafer.

The N-type silicon wafer 1 processed by passivation system 8 is conveyed to the electrode manufacturing loading apparatus 91. The first electrode manufacturing apparatus 92 prepares the back electrode 12 on the N-type silicon wafer 1. The second electrode manufacturing apparatus 94 prepares the front electrode 11, on the N-type silicon wafer 1. Then the N-type silicon wafer 1 is sintered into the finished solar cell by the electrode manufacturing sintering apparatus 95. After the N-type silicon wafer 1 is sintered, the electrode manufacturing detecting apparatus 96 and the electrode manufacturing sorting apparatus 97 are configured to remove an unqualified finished solar cell from the finished solar cell.

In some embodiments, the production line 10 for producing the solar cell further includes an injection device. The injection device is configured to activate hydrogen passivation of the solar cell, so as to improve anti-degradation performance of the solar cell. The injection device may be a device in a related art, and the injection device may be arranged separately. In an implementation, the injection device is an electrical injection device. In another implementation, the injection device is an optical injection device.

In some embodiments, a function of the injection device may alternatively be implemented through another device. For example, the electrode manufacturing sintering apparatus 95 of the electrode manufacturing system 9 is further configured to activate hydrogen passivation of the solar cell.

Optionally, the electrical injection device is connected to the electrode manufacturing sorting apparatus 97, and the carrier is injected into the solar cell through an electric injection method to achieve hydrogen passivation.

In some embodiments, the electrode manufacturing system further includes a laser-enhanced contact optimization (LECO) device configured to perform auxiliary sintering on at least one of the front electrode and the back electrode of the N-type silicon wafer.

The present application further provides a method for producing a solar cell by using the aforementioned production line 10 for producing the solar cell. The method includes the following steps.

Step 1, Cleaning and texturing: cleaning an N-type silicon wafer 1 in a solution, forming a texture structure on the surface of the N-type silicon wafer, and removing a surface damage layer, a cutting line mark, and a metal ion.

Step 2, Boron diffusion: placing a cleaned N-type silicon wafer 1 in a carrier and pushing the carrier into a boron diffusion process furnace tube for boron diffusion, to form a boron doped region 112.

Optionally, Step 3, Laser doping: performing laser local doping on a textured surface of an N-type silicon wafer after boron diffusion, to form a boron heavily doped region 113.

Optionally, Step 4, Oxidation: performing an oxidation process an N-type silicon wafer 1 after laser doping, to protect the boron heavily doped region 113.

Step 5, Etching and polishing: removing a BSG layer on a surface of a front side of the N-type silicon wafer 1, and chemically polishing the back side of the N-type silicon wafer 1.

Step 6, LPCVD: growing an oxide layer 121 and an amorphous silicon layer on a surface of the N-type silicon wafer 1. For example, the oxide layer 121 may include an oxide tunneling layer (SiO₂). For example, the amorphous silicon layer may include an intrinsic amorphous silicon layer.

Step 7, Phosphorus diffusion: pushing a LPCVD processed N-type silicon wafer into a phosphorus diffusion device for multiple phosphorus diffusion to form multiple layers of phosphorus-doped region 122 on the back side, and performing a post-oxidation treatment on an N-type silicon wafer after phosphorus diffusion, so that a phosphorus-doped layer is formed on the back side of the N-type silicon wafer. For example, the phosphorus layer may include a phosphorus-doped polycrystalline silicon layer.

Optionally, Step 8, Laser doping: performing laser local doping on the back side of the N-type silicon wafer after phosphorus diffusion, to form a phosphorus heavily doped region 123.

In some implementations, either a first passivation PECVD device or a second passivation PECVD device may be configured to perform relevant processes corresponding to Step 6 and Step 7, sequentially growing the oxide layer 121 and the phosphorus-doped layer. It can be understood that the same device is not employed here to both perform the passivation process and carry out relevant processes for forming the oxide layer 121 and the phosphorus-doped layer. Instead, a device of the same type as the first passivation PECVD device or the second passivation PECVD device may be used to perform the passivation process. Exemplarily, the aforementioned PECVD device 98 may be used to perform the passivation process.

Optionally, after a step: growing the oxide layer 121, the amorphous silicon layer, and a phosphorus-doped layer on the surface of the N-type silicon wafer 1 by the PECVD device, the method further includes: performing an annealing process on the N-type silicon wafer 1. The annealing process may be performed through an annealing device.

Optionally, Step 9, Oxidation: performing an oxidation process on an N-type silicon wafer after laser doping, to protect the phosphorus heavily doped region 123.

Step 10, Etching: removing a BSG layer, a PSG layer, and an amorphous silicon wrap-around plating on a surface of the N-type silicon wafer 1.

Optionally, Step 11, Annealing: executing an annealing process, and setting step 11 after step 10 to prepare for passivation of the N-type silicon wafer 1 and improve passivation effect.

Step 12, Passivation system processing: passivating the front side of N-type silicon wafer 1 to deposit a passivation layer 111 and a first anti-reflection layer 110 by a passivation System 8, so that front reflection is reduced, lifetime of the carrier is increased, and a current is improved; and growing a second anti-reflection layer 120 on the back side of the N-type silicon wafer 1.

Step 13, Electrode manufacturing process: performing a preparation process of electrodes on two sides of the surface of the N-type silicon wafer 1 by the electrode manufacturing system 9.

Optionally, Step 14, Injection process: injecting a carrier into the solar cell through electrical injection or optical injection by the injection device, so that hydrogen passivation is achieved.

Optionally, the injection device injects the carrier into the solar cell through light injection to achieve hydrogen passivation. Optionally, after a step: injecting a carrier into the solar cell through optical injection by the injection device, the method further includes: performing an annealing process on the N-type silicon wafer 1.

In some feasible implementations, a phosphorus-doped polycrystalline silicon layer is formed over the entire surface on a side of the back side of the N-type silicon wafer 1 by any one of Methods 1 to 5 below.

Method 1: the phosphorus-doped polycrystalline silicon layer is formed directly by the LPCVD process,and an annealing process is then performed in an annealing device to activate doped impurities and promote crystallization of the polysilicon. .

Method 2: an intrinsic polycrystalline silicon layer is formed by the LPCVD process, and then a phosphorus diffusion process is performed on the intrinsic polycrystalline silicon layer in a phosphorus diffusion device to form the phosphorus-doped polycrystalline silicon layer.

Method 3: a phosphorus-doped amorphous silicon layer is first formed by a PECVD device, and an annealing process is then performed in an annealing device to form the phosphorus-doped polycrystalline silicon layer.

Method 4: a phosphorus-doped amorphous silicon layer is first formed by a physical vapor deposition (PVD) device, and then annealed in an annealing device to form the phosphorus-doped polycrystalline silicon layer.

Method 5: an intrinsic amorphous silicon layer is first formed by a LPCVD process, and then a phosphorus diffusion process is performed on the intrinsic amorphous silicon layer in a phosphorus diffusion device. During the phosphorus diffusion process, the amorphous silicon layer is converted into a polycrystalline silicon layer, and finally the phosphorus-doped polycrystalline silicon layer is formed. Optionally, after the phosphorus diffusion process is performed on the intrinsic amorphous silicon layer, the doped polycrystalline silicon layer may be further annealed in an annealing furnace.

It can be understood that in Steps 1 to 14 described above, Method 5 is adopted to form the phosphorus-doped polycrystalline silicon layer.

The present application further includes another method for manufacturing solar cells using the aforementioned production line for producing the solar cell. Method 3 described above is adopted to form the phosphorus-doped polycrystalline silicon layer. As shown in FIG. 2 ( excluding optional steps), the method includes the following steps.

Step 1A, Cleaning and texturing: cleaning an N-type silicon wafer 1 in a solution, forming a texture structure on the surface of the N-type silicon wafer, and removing a surface damage layer, a cutting line mark, and a metal ion. Step 1 may be implemented by the aforementioned texturing device 2.

Step 2A, Boron diffusion: placing a cleaned N-type silicon wafer 1 in a carrier and pushing the carrier into a boron diffusion process furnace tube for boron diffusion, to form a boron doped region 112. Step 2 may be implemented by the aforementioned boron diffusion device 3A.

Optionally, Step 3A, Laser doping: performing laser local doping on a textured surface of an N-type silicon wafer after boron diffusion, to form a boron heavily doped region 113. Step 3 may be implemented by the aforementioned laser doping device 4. Optionally, an oxidation process can be performed after step 8A to oxidize the laser-doped N-type silicon wafer 1 and protect the boron heavily doped region 113.

Step 5A, Etching and polishing: removing a BSG layer on a surface of a front side of the N-type silicon wafer 1, and chemically polishing the back side of the N-type silicon wafer 1. Step 5 may be implemented by the aforementioned etching device 6.

Step 6A, PECVD: growing an oxide layer 121 and a silicon layer on a surface of the N-type silicon wafer 1. Exemplarily, the oxide layer 121 may include a tunneling oxide layer (SiO₂). Exemplarily, the silicon layer may include a doped amorphous silicon layer, and a doping element includes phosphorus. That is, the silicon layer is a phosphorus-doped amorphous silicon layer. Exemplarily, the silicon layer may further include an intrinsic amorphous silicon layer.

Optionally, Step 7A, Phosphorus diffusion: pushing the PECVD processed N-type silicon wafer into the phosphorus diffusion device 7 for phosphorus diffusion. A post-oxidation treatment is performed on the N-type silicon wafer after phosphorus diffusion, so that a phosphorus-doped layer is formed on a back side of the N-type silicon wafer 1. Exemplarily, the phosphorus-doped layer may include the phosphorus-doped polycrystalline silicon layer. It should be noted that if an intrinsic amorphous silicon layer is formed in Step 6, Step 7 shall be a mandatory step, as the phosphorus diffusion process enables the conversion of the intrinsic amorphous silicon layer into a doped polycrystalline silicon layer. If the doped amorphous silicon layer is formed in Step 6, Step 7 shall be a non-mandatory step.

Optionally, Step 8A, Laser doping: performing laser local doping on the back side of the N-type silicon wafer after phosphorus diffusion, to form a phosphorus heavily doped region 123. Optionally, an oxidation process can be performed after step 8A to oxidize the laser-doped N-type silicon wafer 1 and protect the phosphorus heavily doped region 123.

Step 9A, Annealing: pushing a PECVD processed N-type silicon wafer into an annealing device for an annealing process, so as to crystallize the silicon layer obtained in Step 6. Exemplarily, the phosphorus-doped amorphous silicon layer can be converted into a phosphorus-doped polycrystalline silicon layer through the annealing process. The phosphorus-doped polycrystalline silicon layer may also be referred to as the aforementioned phosphorus-doped layer.

Step 10A, Etching: removing a PSG layer and a wrap-around plating on a surface of the N-type silicon wafer 1. Step 10 may be implemented by the aforementioned etching device 6.

Step 12A, Passivation system processing: passivating the front side of N-type silicon wafer 1 to deposit a passivation layer 111 and a first anti-reflection layer 110 by a passivation System 8, so that front reflection is reduced, lifetime of the carrier is increased, and a current is improved; and growing a second anti-reflection layer 120 on the back side of the N-type silicon wafer 1.

Step 13A, Electrode manufacturing process: performing a preparation process of electrodes on two sides of the surface of the N-type silicon wafer 1 by the electrode manufacturing system 9. Optionally, a LECO process is performed to complete auxiliary sintering.

Step 14A, Injection process: achieving hydrogen passivation of a solar cell through electrical injection or optical injection by an injection device.

It should be noted that Steps 1A to 14A described above are not arranged in numerical order. For example, the aforementioned method may not include Step 11A.

In some embodiments, the boron diffusion device 3A is further configured to, during the boron diffusion process to form the boron-doped region 112, introduce nitrogen, oxygen and boron trichloride. A reaction temperature is in a range from 700°C to 900°C, such as in a range from 700°C to 750°C, from 750°C to 800°C, from 800°C to 850°C, or from 850°C to 900°C. A reaction pressure is in a range from 50 mbar to 300 mbar, such as in a range from 50 mbar to 100 mbar, from 100 mbar to 150 mbar, from 150 mbar to 200 mbar, from 200 mbar to 250 mbar, or from 250 mbar to 300 mbar.

In some embodiments, the boron diffusion device 3A is further configured to, while introducing nitrogen, oxygen and boron trichloride, have a gas feeding time in a range from 300 seconds to 1900 seconds, such as in a range from 300 seconds to 700 seconds, from 700 seconds to 1100 seconds, from 1100 seconds to 1500 seconds, or from 1500 seconds to 1900 seconds. A flow rate of boron trichloride is in a range from 100 sccm to 1000 sccm, such as in a range from 100 sccm to 400 sccm, from 400 sccm to 700 sccm, or from 700 sccm to 1000 sccm. A flow rate of nitrogen is in a range from 1000 sccm to 9000 sccm, such as in a range from 1000 sccm to 3000 sccm, from 3000 sccm to 5000 sccm, from 5000 sccm to 7000 sccm, or from 7000 sccm to 9000 sccm. A flow rate of oxygen is in a range from 100 sccm to 1900 sccm, such as in a range from 100 sccm to 400 sccm, from 400 sccm to 700 sccm, from 700 sccm to 1000 sccm, from 1000 sccm to 1300 sccm, from 1300 sccm to 1600 sccm, or from 1600 sccm to 1900 sccm.

In some embodiments, the PECVD device 98 is further configured to, during formation of the tunneling oxide layer, introduce nitrous oxide (such as, N₂O). A reaction temperature is in a range from 380°C to 500°C, such as in a range from 380°C to 410°C, from 410°C to 440°C, from 440°C to 470°C, or from 470°C to 500°C. A reaction pressure is in a range from 1 mbar to 7 mbar, such as in a range from 1 mbar to 2 mbar, from 2 mbar to 3 mbar, from 3 mbar to 4 mbar, from 4 mbar to 5 mbar, from 5 mbar to 6 mbar, or from 6 mbar to 7 mbar.

In some embodiments, the PECVD device 98 further is configured to, while introducing nitrous oxide, have a feeding time in a range from 50 seconds to 650 seconds, such as in a range from 50 seconds to 250 seconds, from 250 seconds to 450 seconds, or from 450 seconds to 650 seconds. A flow rate of nitrous oxide is in a range from 4000 sccm to 20000 sccm, such as in a range from 4000 sccm to 8000 sccm, from 8000 sccm to 12000 sccm, from 12000 sccm to 16000 sccm, or from 16000 sccm to 20000 sccm.

In some embodiments, the PECVD device 98 is further configured to, during formation of the silicon layer, introduce silane, phosphane and hydrogen. A reaction temperature is in a range from 400°C to 450°C, such as in a range from 410°C to 430°C, from 420°C to 440°C, or from 410°C to 450°C. A reaction pressure is in a range from 1 mbar to 8 mbar, such as in a range from 1 mbar to 4 mbar, from 4 mbar to 6 mbar, or from 6 mbar to 8 mbar.

In some embodiments, the PECVD device 98 is further configured to, while introducing silane, phosphane and hydrogen, have a gas feeding time in a range from 200 seconds to 2000 seconds, such as in a range from 200 seconds to 500 seconds, from 500 seconds to 800 seconds, from 800 seconds to 1100 seconds, from 1100 seconds to 1400 seconds, from 1400 seconds to 1700 seconds, or from 1700 seconds to 2000 seconds. A flow rate of silane is in a range from 2000 sccm to 8000 sccm, such as in a range from 2000 sccm to 4000 sccm, from 4000 sccm to 6000 sccm, or from 6000 sccm to 8000 sccm. A flow rate of phosphane is in a range from 400 sccm to 2800 sccm, such as in a range from 400 sccm to 800 sccm, from 800 sccm to 1200 sccm, from 1200 sccm to 1600 sccm, from 1600 sccm to 2000 sccm, from 2000 sccm to 2400 sccm, or from 2400 sccm to 2800 sccm. A flow rate of hydrogen is in a range from 4000 sccm to 24000 sccm, such as in a range from 4000 sccm to 8000 sccm, from 8000 sccm to 12000 sccm, from 12000 sccm to 16000 sccm, from 16000 sccm to 20000 sccm, or from 2000 sccm to 24000 sccm.

It can be understood that the above-mentioned gas feeding time and flow rates are related to a size of the furnace tube. For example, a larger furnace tube requires a higher flow rate or a longer gas feeding time to reach a preset reaction pressure inside the furnace tube.

The present application provides a production line 10 for producing the solar cell, and cleaning and texturing, boron diffusion, laser doping, etching and polishing, PECVD, annealing, etching, passivation system processing, electrode manufacturing process, and injection process are sequentially performed on an N-type silicon wafers 1. Through adding some devices, a production line for a passivated emitter and rear cell with selective emitter (PERC-SE) cell is greatly adapted and utilized, with almost no waste of devices of the production line for the PERC-SE cell, and lifecycle of the production line for the PERC cell is extended.

The carrier mentioned above can be a quartz boat, or a boat made of other materials, such as a boat made of silicon carbide material.

What is claimed is:

1. A production line for producing a solar cell, applied to manufacturing an N-type silicon wafer into a solar cell, comprising:
a texturing device, configured to perform a texturing process of the N-type silicon wafer;
a boron diffusion device, configured to perform a boron diffusion process of the N-type silicon wafer to form a boron-doped region;
an etching device, configured to perform an etching process and a polishing process of the N-type silicon wafer;
a plasma enhanced chemical vapor deposition (PECVD) device, configured to form a tunneling oxide layer and a silicon layer on a back side of the N-type silicon wafer;
a passivation system, configured to perform a passivation layer process, a front film process and a back film process of the N-type silicon wafer; and
an electrode manufacturing system, configured to perform a preparation process of electrodes on two sides of the N-type silicon wafer to form the solar cell.

2. The production line according to claim 1, further comprising:
an annealing device, configured to perform an annealing process of the N-type silicon wafer.

3. The production line according to claim 1, wherein the PECVD device is further configured to perform an annealing process on the N-type silicon wafer.

4. The production line according to claim 1, wherein the silicon layer comprises a doped amorphous silicon layer, and a doping element comprises phosphorus.

5. The production line according to claim 1, wherein the boron diffusion device is further configured to, during formation of the boron-doped region, introduce nitrogen, oxygen and boron trichloride; a reaction temperature is in a range from 700°C to 900°C, and a reaction pressure is in a range from 50 mbar to 200 mbar.

6. The production line according to claim 1, wherein the PECVD device is further configured to, during formation of the tunneling oxide layer, introduce nitrous oxide (N₂O); a reaction temperature is in a range from 380°C to 500°C, and a reaction pressure is in a range from 1 mbar to 7 mbar.

7. The production line according to claim 1, wherein the silicon layer comprises an intrinsic amorphous silicon layer, and the production line for producing the solar cell further comprises:
a phosphorus diffusion device, configured to perform a phosphorus diffusion process of the N-type silicon wafer, wherein the phosphorus diffusion process is performed after formation of the intrinsic amorphous silicon layer.

8. The production line according to claim 7, wherein the phosphorus diffusion device comprises a phosphorus diffusion loading and unloading system, a phosphorus diffusion purification table, a phosphorus diffusion furnace cabinet, a phosphorus diffusion gas cabinet, and a phosphorus diffusion phosphorus source cabinet.

9. The production line according to claim 1, wherein the texturing device comprises a texturing loading apparatus, a texturing pre-cleaning tank, a texturing apparatus, a texturing post-cleaning tank, a texturing pickling tank, a texturing pre-dehydration tank, a texturing drying tank, and a texturing unloading apparatus connected in sequence;
the texturing loading apparatus is configured to move the N-type silicon wafer to the texturing pre-cleaning tank for cleaning;
the texturing pre-cleaning tank is configured to remove an impurity on a surface of the N-type silicon wafer;
the texturing apparatus is configured to form a texture structure on the surface of the N-type silicon wafer by using an alkaline solution;
the texturing post-cleaning tank is configured to clean the N-type silicon wafer after the texture structure is formed on the surface of the N-type silicon wafer to remove an impurity on the surface of the N-type silicon wafer;
the texturing pickling tank is configured to pickle the N-type silicon wafer with acid to neutralize the alkaline solution and remove a metal ion from the surface of the N-type silicon wafer;
the texturing pre-dehydration tank is configured to dehydrate the N-type silicon wafer after the N-type silicon wafer is pickled;
the texturing drying tank is configured to dry the N-type silicon wafer after the N-type silicon wafer is dehydrated; and
the texturing unloading apparatus is configured to convey the N-type silicon wafer completing the texturing process to the boron diffusion device for further processing.

10. The production line according to claim 1, wherein the passivation system comprises:
a first passivation module, configured to perform the passivation layer process, wherein the first passivation module comprises an atomic layer deposition (ALD) device or a first passivation PECVD device; and
a second passivation module, configured to perform the front film process and the back film process, wherein the second passivation module comprises a second passivation PECVD device.

11. The production line according to claim 10, wherein the passivation system comprises a passivation loading and unloading apparatus, a passivation purification table, a passivation furnace body, a passivation gas cabinet, and a passivation vacuum pump; and
the passivation loading and unloading apparatus, the passivation purification table, the passivation furnace body, the passivation gas cabinet and the passivation vacuum pump are applied to one or more of ALD devices, the first passivation PECVD device and the second passivation PECVD device.

12. The production line according to claim 10, wherein
the passivation layer process comprises depositing an aluminum oxide passivation layer on a surface of the N-type silicon wafer;
the front film process comprises depositing at least one of Si_{y}Nₓ Si_{z}NₓO_{y} and SiO₂ on the front side of the N-type silicon wafer; and
the back film process comprises depositing at least one of Si_{y}Nₓ Si_{z}NₓO_{y} and SiO₂ on a back side of the N-type silicon wafer.

13. The production line according to claim 1, wherein the boron diffusion device comprises:
a first loading and unloading system, wherein the first loading and unloading system comprises a first loading wafer-guiding assembly, a first unloading wafer-guiding assembly, a first wafer-guiding circulation conveying mechanism, a first silicon wafer grabbing apparatus, a first loading carrying mechanism, a first unloading carrying mechanism, and a first carrier circulation mechanism;
a first carrier conveying and purifying system, wherein the first carrier conveying and purifying system comprises a first carrier carrying system, a first carrier pushing system, a first purifying and cooling system, a first transmission system, and a first purification table frame; and
a first furnace tube system, wherein the first furnace tube system comprises a first furnace tube rack and a first process furnace tube, and the first process furnace tube comprises a boron diffusion furnace tube.

14. The production line according to claim 13, wherein
the first loading and unloading system comprises a wafer guiding apparatus, and the wafer guiding apparatus comprises the first loading wafer-guiding assembly, the first unloading wafer-guiding assembly, the first wafer-guiding circulation conveying mechanism, the first loading carrying mechanism, the first unloading carrying mechanism, and the first carrier circulation mechanism;
the first silicon wafer grabbing apparatus comprises a six-axis robot and a silicon wafer grabbing and releasing mechanism, the silicon wafer grabbing and releasing mechanism is configured to control suction to the N-type silicon wafer and turn-over of the N-type silicon wafer, and the six-axis robot is configured to control movement of the N-type silicon wafer through the silicon wafer grabbing and releasing mechanism;
the first loading and unloading system further comprises a silicon wafer loading system and a silicon wafer unloading system, the silicon wafer loading system comprises the first loading wafer-guiding assembly, the first silicon wafer grabbing apparatus, the first loading carrying mechanism, and the first carrier circulation mechanism, and the silicon wafer unloading system comprises the first unloading wafer-guiding assembly, the first silicon wafer grabbing apparatus, the first unloading carrying mechanism, and the first carrier circulation mechanism;
the first carrier carrying system, the first carrier pushing system and the first transmission system are installed inside the first purification table frame, and the first purifying and cooling system is located outside the first purification table frame;
the first transmission system is configured to transfer a carrier loaded with an unprocessed N-type silicon wafer located in the first loading and unloading system to the first carrier carrying system, and transfer a carrier loaded with a processed N-type silicon wafer to the first loading and unloading system, so as to perform a carrier interaction between the first carrier carrying system and the first loading and unloading system;
the first carrier carrying system is configured to move the carrier loaded with the unprocessed N-type silicon wafer to the first carrier pushing system;
the first carrier pushing system is configured to move the carrier loaded with the unprocessed N-type silicon wafer to the first furnace tube system for processing, and the first carrier pushing system is further configured to move out the carrier loaded with the processed N-type silicon wafer and move the carrier loaded with the processed N-type silicon wafer to the first transmission system through the first carrier carrying system; and
the first purifying and cooling system is configured to purify a gas of the first carrier conveying and purifying system.

15. The production line according to claim 2, wherein the annealing device comprises:
a second loading and unloading system, wherein the second loading and unloading system comprises a second loading wafer-guiding assembly, a second unloading wafer-guiding assembly, a second wafer-guiding circulation conveying mechanism, a second silicon wafer grabbing apparatus, a second loading carrying mechanism, a second unloading carrying mechanism, and a second carrier circulation mechanism;
a second carrier conveying and purifying system, wherein the second carrier conveying and purifying system comprises a second carrier carrying system, a second carrier pushing system, a second purifying and cooling system, a second transmission system, and a second purification table frame; and
a second furnace tube system, wherein the second furnace tube system comprises a second furnace tube rack and a second process furnace tube, and the second process furnace tube comprises an annealing furnace tube.

16. The production line according to claim 1, wherein the etching process is further configured to remove at least one of boro silicate glass (BSG) and phospho silicate glass (PSG);
the etching device comprises an alkali polishing and etching loading apparatus, an alkali polishing and etching protection apparatus, an alkali polishing and etching performing apparatus, an alkali polishing and etching alkali washing apparatus, an alkali polishing and etching pickling apparatus, and an alkali polishing and etching unloading apparatus.

17. The production line according to claim 1, further comprising:
a laser doping device, configured to perform laser local boron doping on a front side of the N-type silicon wafer to form a boron heavily doped region; and
an oxidation system, is configured to perform an oxidation process of the N-type silicon wafer;
wherein the laser doping device comprises a laser doping loading end, a laser processing cavity, and a laser unloading end; and
a laser process device is provided in the laser processing cavity, and the laser process device is configured to perform laser grooving on a textured surface, and perform front laser local doping on a grooving region of the N-type silicon wafer after boron diffusion to form the boron heavily doped region.

18. The production line according to claim 1, wherein the electrode manufacturing system comprises an electrode manufacturing loading apparatus, a first electrode manufacturing apparatus, an electrode manufacturing drying apparatus, a second electrode manufacturing apparatus, an electrode manufacturing sintering apparatus, an electrode manufacturing detecting apparatus, and an electrode manufacturing sorting apparatus;
the electrode manufacturing loading apparatus is configured to receive the N-type silicon wafer processed by the passivation system;
the first electrode manufacturing apparatus is configured to prepare a back electrode on the N-type silicon wafer;
the second electrode manufacturing apparatus is configured to prepare a front electrode on the N-type silicon wafer;
the electrode manufacturing sintering apparatus is configured to sinter the N-type silicon wafer after the electrodes are manufactured into a finished solar cell; and
the electrode manufacturing detecting apparatus and the electrode manufacturing sorting apparatus are configured to remove an unqualified finished solar cell from the finished solar cell.

19. The production line according to claim 18, wherein the electrode manufacturing sintering apparatus is further configured to perform a light injection process of the N-type silicon wafer.

20. The production line according to claim 18, wherein the electrode manufacturing system further comprises a laser-enhanced contact optimization (LECO) device configured to perform auxiliary sintering on at least one of the front electrode and the back electrode of the N-type silicon wafer.
